(19) United States
(12) Patent Application Publication
(10) Pub. No.: US 2010/0243461 A1
(43) Pub. Date: Sep. 30, 2010

(54) METHOD OF FABRICATING CIRCUIT BOARD

(75) Inventor: Mitsuyuki TSURUMI, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/748,464

(22) Filed: Mar. 29, 2010

(30) Foreign Application Priority Data
Mar. 31, 2009 (JP) 2009-087656

(51) Int. Cl. H05K 3/10; C25D 5/02

(52) U.S. Cl. 205/125

(57) ABSTRACT

A method of fabricating a circuit board includes: forming an adhesion auxiliary layer on a surface of an insulating base board; forming an adhesion layer on a surface of the adhesion auxiliary layer, the adhesion layer comprising a polymer compound having a polymerizable group and a functional group capable of interacting with a plating catalyst or a precursor thereof; fixing the adhesion layer to the adhesion auxiliary layer by applying energy to the adhesion layer; applying a plating catalyst or a precursor thereof to the adhesion layer; forming a first metal film by electroless plating on the adhesion layer; and performing electroplating by using the first metal film; and the method further includes partly removing, by irradiating a laser beam, an area corresponding to a non-circuit portion in any of the adhesion auxiliary layer, the adhesion layer, or the first metal film.

### CROSS-REFERENCE TO RELATED APPLICATIONS

This application claims priority under 35USC 119 from Japanese Patent Application No. 2009-087656 filed on Mar. 31, 2009, the disclosure of which is incorporated herein by reference.

### BACKGROUND OF THE INVENTION

1. Field of the Invention

The present invention relates to a method of fabricating a circuit board.

2. Description of the Related Art

Circuit boards having a circuit formed on a surface of an insulating base board have been widely used so far.

A method of fabricating the circuit boards is described in, for example, Japanese Patent Application Laid-Open (JP-A) No. 7-66533, which includes forming an underlying layer for plating that is made of a plating catalyst, a compound thereof, a metal film or the like on a surface of an insulating base board; irradiating laser beam or the like onto the underlying layer for plating in accordance with a pattern of non-circuit portion so as to remove the irradiated portion of the underlying layer for plating; and then plating the underlying layer for plating so as to form a circuit portion.

In this method of fabricating a circuit board, the underlying layer for plating is formed by applying a plating catalyst directly to the base board or by adhering a metal foil onto the base board. Thus, the adhesion between the underlying layer for plating and the base board is weak, and the surface of the base board is required to be roughened in order to obtain sufficient adhesion. When the surface of the base board is roughened and the irregularities of the surface formed by roughening becomes so fine as to be close to the fineness of a desired circuit to be formed, the roughening exerts significant influence on the fine wiring forms or patterns of a fine circuit, as a result of which a circuit with a desired fine pattern may not be formed or disconnection or electrical short circuit may occur during the formation of the circuit.

Further, JP-A No. 2006-60149 discloses a method of forming a conductive pattern. In this method, a compound having a double bond is coated on the surface of an insulating resin layer formed on an insulating base board, UV light is patternwise irradiated so as to form a graft polymer on the insulating resin layer whereby a pattern formed by a graft-polymer-generated region and a graft-polymer-absent region is formed, and then the graft-polymer-generated region is subjected to electroless plating or electroplating to form the conductive pattern.

In this method, the formation of the pattern formed by the graft-polymer-generated region and the graft-polymer-absent region requires removal of the other region than a region that has been patternwise irradiated with the UV light, through a development process using a developer. Further, insufficient development causes residues to remain between the conductive patterns, and resultantly causes decrease in product quality.

In view of the above, a method is requested by which the residues between conductive patterns (non-circuit portions) are removed in a relatively simple manner in fabrication of fine conductive patterns (circuits).

### SUMMARY OF THE INVENTION

The invention has been made in consideration of these conventional problems, and provides a method of fabricating a circuit board.

A method of fabricating a circuit board according to the present invention includes, in the following order, (a) forming an adhesion auxiliary layer on a surface of an insulating base board; (b) forming an adhesion layer on a surface of the adhesion auxiliary layer, the adhesion layer including a polymer compound having a polymerizable group and a functional group capable of interacting with a plating catalyst or a precursor thereof; (c) fixing the adhesion layer to the adhesion auxiliary layer by applying energy to the adhesion layer; (d) applying a plating catalyst or a precursor thereof to the adhesion layer that is fixed to the adhesion auxiliary layer; (e) forming a first metal film by electroless plating on the adhesion layer; and (f) performing electroplating by using the first metal film formed by electroless plating,

wherein the method further includes (g) partly removing, by irradiating a laser beam, an area corresponding to a non-circuit portion in any of: the adhesion auxiliary layer prior to (b) the forming of the adhesion layer, the adhesion layer that is fixed to the adhesion auxiliary layer prior to (d) the applying of a plating catalyst or a precursor thereof, the adhesion layer having had the plating catalyst or a precursor thereof applied thereto prior to (e) the forming of the first metal film, or the first metal film prior to (f) the performing of the electroplating.

Another method of fabricating a circuit board according to the present invention includes, in the following order, (a) forming an adhesion auxiliary layer on a surface of an insulating base board; (b) forming an adhesion layer on a surface of the adhesion auxiliary layer, the adhesion layer including a plating catalyst or a precursor thereof and a polymer compound having a polymerizable group and a functional group capable of interacting with the plating catalyst or precursor thereof; (c) fixing the adhesion layer to the adhesion auxiliary layer by applying energy to the adhesion layer; (e) forming a first metal film by electroless plating on the adhesion layer that is fixed to the adhesion auxiliary layer; and (f) performing electroplating by using the first metal film formed by electroless plating,

wherein the method further includes (g) partly removing, by irradiating a laser beam, an area corresponding to a non-circuit portion in any of: the adhesion auxiliary layer prior to (b) the forming of the adhesion layer, the adhesion layer that is fixed to the adhesion auxiliary layer prior to (e) the forming of the first metal film, or the first metal film prior to (f) the performing of the electroplating.

In the present invention, (a) the forming of the adhesion auxiliary layer is preferably performed using any one of dip coating, spray coating or ink jet coating.

(b) the forming of the adhesion layer is preferably performed using any one of dip coating, spray coating or ink jet coating.

The thickness of the first metal film formed in the (e) forming of the first metal film is preferably from 0.2 μm to 2.0 μm.

In the present invention, the polymer compound used in the (b) the forming of the adhesion layer and having a polymerizable group and a functional group capable of interacting with the plating catalyst or a precursor thereof is preferably a hydrophobic compound.

The polymer compound having a polymerizable group and a functional group capable of interacting with the plating catalyst or precursor thereof is preferably a compound having a cyano group as a functional group capable of interacting with the plating catalyst or a precursor thereof.

According to the present invention, a method of fabricating a circuit board is provided, with which a fine-pattern circuit board that has a circuit exhibiting excellent adhesion to a base board and in which the amount of residues in a non-circuit portion is reduced can be fabricated in a relatively simple manner.

Use of the method of fabricating a circuit board according to the present invention allows formation of a fine-pattern circuit exhibiting excellent adhesion to the base board even when roughening of the insulating base board is not conducted.

### DETAILED DESCRIPTION OF THE INVENTION

Hereinafter, the present invention will be described in detail.

The method of fabricating a circuit board according to the present invention includes, in the following order, (a) forming an adhesion auxiliary layer on a surface of an insulating base board; (b) forming an adhesion layer on a surface of the adhesion auxiliary layer, the adhesion layer including a polymer compound having a polymerizable group and a functional group capable of interacting with a plating catalyst or a precursor thereof; (c) fixing the adhesion layer to the adhesion auxiliary layer by applying energy to the adhesion layer; (d) applying a plating catalyst or a precursor thereof to the adhesion layer that is fixed to the adhesion auxiliary layer; (e) forming a first metal film by electroless plating on the adhesion layer; and (f) performing electroplating by using the first metal film formed by electroless plating,

wherein the method further includes (g) partly removing, by irradiating a laser beam, an area corresponding to a non-circuit portion in any of: the adhesion auxiliary layer prior to (b) the forming of the adhesion layer, the adhesion layer that is fixed to the adhesion auxiliary layer prior to (d) the applying of a plating catalyst or a precursor thereof, the adhesion layer having had the plating catalyst or a precursor thereof applied thereto prior to (e) the forming of the first metal film, or the first metal film prior to (f) the performing of the electroplating.

Each process included in the present invention will be described successively.

Process (a) of Forming Adhesion Auxiliary Layer

In the process (a) of forming an adhesion auxiliary layer, the adhesion auxiliary layer is formed on a surface of an insulating base board. The adhesion auxiliary layer includes preferably an active species that generates an active site capable of interacting with the polymer compound used in the process (b) of forming the adhesion layer described below, the polymer compound having a polymerizable group and a functional group capable of interacting with a plating catalyst or a precursor thereof. The adhesion auxiliary layer is preferably, for example, a polymerization initiating layer that includes a polymerization initiator or a polymerization initiating layer that is made of a resin having a functional group capable of initiating polymerization.

More specific examples of the adhesion auxiliary layer according to the present invention includes a layer that includes a polymer compound and a polymerization initiator, a layer that includes a polymerizable compound and a polymerization initiator, and a layer that is made of a resin having a functional group capable of initiating polymerization.

In the present invention, the base board adjacent to the adhesion auxiliary layer is an insulating base board. Therefore, the adhesion auxiliary layer preferably includes an insulating resin from the viewpoint of improving adhesion to the insulating base board.

An embodiment of the adhesion auxiliary layer is described below which includes an insulating resin.

The insulating resin that is used to form the adhesion auxiliary layer may include an insulating resin that is the same as or different from the electrically insulating resin forming the insulating base board, and it is preferable to use an insulating resin that is similar to the insulating resin forming the insulating base board in respect of thermal properties, such as glass transition temperature, elastic modulus, and linear expansion coefficient. Specifically, it is preferable to use the same kind of insulating resin as the insulating resin forming the insulating base board, from the viewpoint of enhancing the adhesion to the insulating base board.

Specific examples of the insulating resin include a thermosetting resin, a thermoplastic resin, and a mixture thereof. Examples of the thermosetting resin include an epoxy resin, a phenol resin, a polyimide resin, a polyester resin, a bismaleimide resin, a polyolefin resin, and an isocyanate resin.

Examples of the thermoplastic resin include phenoxy resin, polyether sulfone, polysulfone, polyphenylene sulfone, polyphenylene sulfide, polyphenyl ether, and polyether imide.

Either of thermosetting resin or thermoplastic resin may be used alone, or, alternatively, a combination of two or more selected from thermosetting resins and thermoplastic resins may be used so as to compensate the shortcomings of the respective resins and exert improved effects. For example, at least one thermosetting resin and at least one thermoplastic resin may be used in combination.

As an insulating resin used in the adhesion auxiliary layer, a resin may be used that has a molecular framework that generates an active site capable of interacting with the polymer compound that has a polymerizable group and a functional group capable of interacting with the plating catalyst or a precursor thereof. For example, a polyimide having a polymerization initiating portion in the molecular framework thereof, such as those described in the paragraph numbers of from [0018] to [0078] of JP-A No. 2005-307140, may be used.

When the adhesion auxiliary layer is formed, a compound having a polymerizable double bond, such as an acrylate compound or a methacrylate compound, may be used in order to allow cross-linking to proceed in the layer. In particular, a compound having two or more polymerizable double bonds is preferably used. Other examples of the compound having a polymerizable double bond include a resin obtained by (meth)acrylating a part of a thermosetting resin or a part of a thermoplastic resin by using, for example, methacrylic acid or acrylic acid. Here, examples of the thermosetting resin or the thermoplastic resin include epoxy resin, phenol resin, polyimide resin, polyolefin resin, and fluororesin.

As long as the effect of the present invention is not impaired, various kinds of compounds may be added to the adhesion auxiliary layer of the present invention in accordance with objectives.

Specific examples of the compounds include a material that reduces stress upon heating such as rubber or SBR latex, a binder for improving film properties, a plasticizer, a surfactant, and a viscosity modifier.

The adhesion auxiliary layer of the present invention may include a composite (composite material) composed of a resin and one or more other components in order to improve film properties including mechanical strength, heat resistance, weather resistance, flame retardancy, water resistance, and electrical properties. Examples of such materials that is used to prepare the composite include paper, glass fibers, silica particles, phenol resin, polyimide resin, bismaleimide triazine resin, fluororesin, and polyphenylene oxide resin.

The adhesion auxiliary layer may optionally include one kind of, or two or more kinds of, filler used in general resin materials for circuit boards. Examples of the filler include an inorganic filler such as silica, alumina, clay, talc, aluminum hydroxide, or calcium carbonate, and an organic filler such as cured epoxy resin, cross-linked benzoguanamine resin, or cross-linked acrylic polymer.

The adhesion auxiliary layer may optionally include one kind of, or two or more kinds of, additive, examples of which include a colorant, a flame retardant, an adhesion improver, a silane coupling agent, an anti-oxidant, and a UV light absorber.

When these materials are incorporated, the amount of each material is preferably in the range of from 0% to 200% by mass, and more preferably in the range of from 0% to 80% by mass, with respect to the resin that serves as a main component. When the adhesion auxiliary layer and the base board adjacent thereto exhibit the same or similar heat and electrical properties, addition of these additives is not necessarily required. When the additives are used in the range of more than 200% by mass with respect to the resin, the properties that the resin originally possesses, such as strength, are possibly lowered.

The adhesion auxiliary layer preferably includes an active species (compound) which generates an active site capable of interacting with the polymer compound that has a polymerizable group and a functional group capable of interacting with the plating catalyst or a precursor thereof and that is used when the adhesion layer is formed. The generation of the active site may be achieved by application of energy. The energy is preferably at least one selected from light (such as UV light, visible light, or X-rays), a plasma (of oxygen, nitrogen, carbon dioxide, argon or the like), heat, electricity, or the like. Further, the active site may be generated by chemically decomposing the surface using, for example, an oxidative liquid (for example, a potassium permanganate solution).

Examples of the active species include a heat polymerization initiator and a photopolymerization initiator. Specific examples thereof include those described in paragraph [0044] of JP-A No. 2007-154306 and the polymers having pendant functional groups having polymerization initiating ability at side chains and described in paragraphs to [0158] of JP-A No. 2004-161995. Known polymerization initiators, such as those described above, may be appropriately selected and used in accordance with objectives. Among these, use of photopolymerization is preferable from the viewpoint of suitability for production. Therefore, use of a photopolymerization initiator is preferable.

There is no particular limitation on the photopolymerization initiator as long as the photopolymerization initiator is active to the irradiated actinic light and has a capability of generating an active site. Examples of photopolymerization initiators that can be used include radical polymerization initiators, anion polymerization initiators, and cation polymerization initiators. Radical polymerization initiators are preferable from the viewpoint of reactivity.

The amount of the polymerization initiator to be incorporated in the adhesion auxiliary layer is preferably from 0.1% to 50% by mass, and more preferably from 1.0% to 30% by mass, relative to the total solid content of the adhesion auxiliary layer.

The adhesion auxiliary layer of the present invention may be prepared in the following manner: the respective components, such as those described above, are dissolved in a solvent that is capable of dissolving the components, the resulting solution is applied onto a surface of an insulating base board by using a method such as coating, and then the resulting coating film is cured by heating or light irradiation.

When forming of the adhesion auxiliary layer, the curing of the coating film by heating and/or light irradiation is preferably performed.

In particular, it is preferable to perform preliminary curing of the coating film by light irradiation after drying the coating film by heating. This is because, when the adhesion auxiliary layer includes a polymerizable compound, curing proceeds to a moderate degree during the preliminary curing, thereby effectively preventing a defect such as separation of the adhesion layer and adhesion auxiliary layer together after the adhesion layer is fixed on the adhesion auxiliary layer.

Regarding the heating time and temperature, a condition under which the solvent used for coating is sufficiently dried off may be selected. But preferably the temperature is selected to be 100° C. or lower and the drying time is selected to be within 30 minutes, from the viewpoint of production adaptability, and more preferably a heating condition of from 40° C. to 80° C. of drying temperature and within 10 minutes of drying time is selected.

The adhesion auxiliary layer is formed on the surface of the insulating base board by employing a known layer forming process such as a coating process, a transfer process, or a printing process. In particular, it is preferable to use a method selected from dip coating, spray coating or ink jet coating from the viewpoint of facilitating coating on a three-dimensionally-shaped material.

The solvent that is used when the adhesion auxiliary layer is formed by coating is not particularly limited as long as the solvent is capable of dissolving the components as described above. From the viewpoint of facilitating drying and workability, a solvent of which boiling point is not excessively high is preferable. Specifically, a solvent having a boiling point of from 40° C. to 150° C. may be selected.

Specifically, cyclohexanone, methyl ethyl ketone, and other solvents described in paragraph [0045] of JP-A No. 2007-154306 may be used. The solvents exemplified above each may be used singly, or as a mixture of two or more thereof. The solid content of the coating liquid may appropriately be from 2% to 50% by mass.

When a transfer process is used for forming the adhesion auxiliary layer, a transfer laminate having a two-layered structure formed by the adhesion layer and the adhesion auxiliary layer may be prepared, and then the adhesion layer and the adhesion auxiliary layer may be transferred to the surface of the insulating base body at once through a lamination process.

The thickness of the adhesion auxiliary layer in the present invention is generally in the range of from 0.1 μm to 10 μm, and preferably from 0.2 μm to 5 μm.

Process (b) of Forming Adhesion Layer

In the process (b) of forming an adhesion layer, an adhesion layer is formed on a surface of the adhesion auxiliary layer formed by the process (a), the adhesion layer including a polymer compound having a polymerizable group and a functional group capable of interacting with a plating catalyst or a precursor thereof.

The polymer compound (specific polymer) that has a polymerizable group and a functional group capable of interacting with a plating catalyst or a precursor thereof and is used in this process is described. The functional group capable of interacting with a plating catalyst or a precursor thereof is hereinafter referred to as “interaction group”.

The specific polymer effectively adsorbs the plating catalyst or a precursor thereof because the polymer has an interaction group, and the specific polymer is directly chemically bonded to the adhesion auxiliary layer adjacent thereto because the polymer has a polymerizable group.

Specific Polymer

Examples of the interaction group in the specific polymer in the present invention include polar groups (hydrophilic groups) and non-dissociative functional groups (functional groups that do not generate a proton by dissociation) such as groups capable of polydentate coordination, nitrogen-containing functional groups, sulfur-containing functional groups, and oxygen-containing functional groups. In particular, use of a non-dissociative functional group that serves as a site exhibiting metal ion adsorbability is preferable from the viewpoint of reducing water absorption and moisture absorption of the adhesion layer.

In order to reduce the water absorption and moisture absorption of the adhesion layer, the specific polymer as a whole is preferably hydrophobic even if the specific polymer has at least one of a polar group (hydrophilic group) or a non-dissociative functional group (a functional group that does not form a proton by dissociation) such as a group capable of forming a polydentate coordination, a nitrogen-containing functional group, a sulfur-containing functional group, or an oxygen-containing functional group.

The expression “the specific polymer is hydrophobic” means that the specific polymer has low water absorption, low water swellability, and low wettability against water, and more specifically means that a film that is formed using only the specific polymer (specifically, a film that is obtained through the processes (a) to (c) of the present invention) preferably satisfies any of the following conditions 1 to 4, and more preferably satisfies all of the following conditions 1 to 4. The term “hydrophobic compound” as used herein in connection with the specific polymer also has the meaning described above.

Condition 1: saturation water absorption is from 0.01% to 10% by mass in an environment of 25° C. and 50% RH,

Condition 2: saturation water absorption is from 0.05% to 20% by mass in an environment of 25° C. and 95% RH,

Condition 3: water absorption is from 0.1% to 30% by mass after 1 hour immersion in 100° C. boiling water, and

Condition 4: surface contact angle is from 50 degrees to 150 degrees after 5 μL of distilled water is dropped on the film and left for 15 seconds in an environment of 25° C. and 50% RH.

Examples of the polar group include: a functional group having a positive charge, such as ammonium or phosphonium; and an acidic group that has a negative charge or that can dissociate to have a minus charge, such as a sulfonic acid group, a carboxyl group, a phosphoric acid group, or a phosphonic acid group. Such groups dissociate and adsorb metal ions as counter ions.

A nonionic polar group such as a hydroxy group, an amido group, a sulfoneamido group, an alkoxy group, or a cyano group is also usable.

Further examples of polar groups that can be used include an imino group, a primary or secondary amino group, an amido group, a urethane group, a hydroxyl group (the scope of which includes a phenolic hydroxyl group), and a thiol group.

The non-dissociative functional group is, specifically, preferably a group capable of coordinating to a metal ion, a nitrogen-containing functional group, a sulfur-containing functional group, an oxygen-containing functional group, or the like. Specific examples thereof include: a nitrogen-containing functional group such as an imide group, a pyridine group, a tertiary amino group, an ammonium group, a pyrrolidone group, an amidino group, a group containing a triazine ring structure, a group containing an isocyanuric structure, a nitro group, a nitroso group, an azo group, a diazo group, an azido group, a cyano group, or a cyanate group (R—O—CN); an oxygen-containing functional group such as an ether group, a carbonyl group, an ester group, a group containing an N-oxide structure, a group containing an S-oxide structure, or a group containing an N-hydroxy structure; a sulfur-containing functional group such as a thioether group, a thioxy group, a sulfoxide group, a sulfone group, a sulfite group, a group containing a sulfoxyimine structure, a group containing a sulfoxinium salt structure, or a group containing a sulfonic ester structure; a phosphorus-containing functional group such as a phosphine group; a group containing a halogen atom such as chlorine or bromine; and an unsaturated ethylene group. Further examples include an imidazole group, a urea group, and a thiourea group, provided that these groups are not dissociative due to the relationship with adjacent atoms and/or atomic groups.

Among these, an ether group (more specifically, a structure represented by —O—(CH₂)ₙ—O— (n represents an integer of from 1 to 5)) or a cyano group is preferable because these groups have a high polarity and a high ability to adsorb the plating catalyst or a precursor thereof, and a cyano group is particularly preferable.

Generally, a higher polarity tends to increase the water absorption. However, cyano groups interact with each other in the adhesion layer in such a manner as to mutually cancel the polarity thereof, so that the layer becomes dense and the polarity of the adhesion layer as a whole decreases, as a result of which the water absorption decreases. In addition, when the catalyst plating catalyst or a precursor thereof is applied using a good solvent for the adhesion layer, the cyano groups are solvated and the interaction between the cyano groups disappears, so that the cyano groups become able to interact with the plating catalyst or a precursor thereof. Therefore, the adhesion layer having the cyano groups is preferable in that the layer exhibits contradictory properties of low moisture absorption and capability of effectively interacting with the plating catalyst or a precursor thereof.

As the interaction group in the present invention, an alkylcyano group is more preferable for the following reason. In an aromatic cyano group, electrons are attracted to the aromatic ring thereof, and an ability of donating unpaired electrons, which is important in providing capability of adsorbing the plating catalyst or a precursor thereof, is lowered. In contrast, in the case of the alkylcyano group, no aromatic ring is bonded thereto, so that the alkylcyano group is preferable in terms of the capability of adsorbing the plating catalyst or a precursor thereof.

In the present invention, the specific polymer is preferably a polymer that is obtained by introducing, as a polymerizable group, an ethylenic addition-polymerizable unsaturated group (polymerizable group) such as a vinyl group, an allyl group, or a (meth)acryl group into a homopolymer or a copolymer obtained using a monomer having an interaction group. The polymer having an interaction group and a polymerizable group has a polymerizable group at least at a terminal of the main chain thereof or at a side chain thereof, and preferably has a polymerizable group at a side chain thereof.

Regarding specific synthesis methods, raw material monomers used therein, preferable ranges of ratios of the units derived from the raw material monomers, and the like, the method described in paragraphs [0107] to [0115] of WO 08/050,715 may be applied.

Specific examples of the polymer having an interaction group and a polymerizable group that is suitably used in the present invention are described below, but the present invention is in no way limited by these examples.

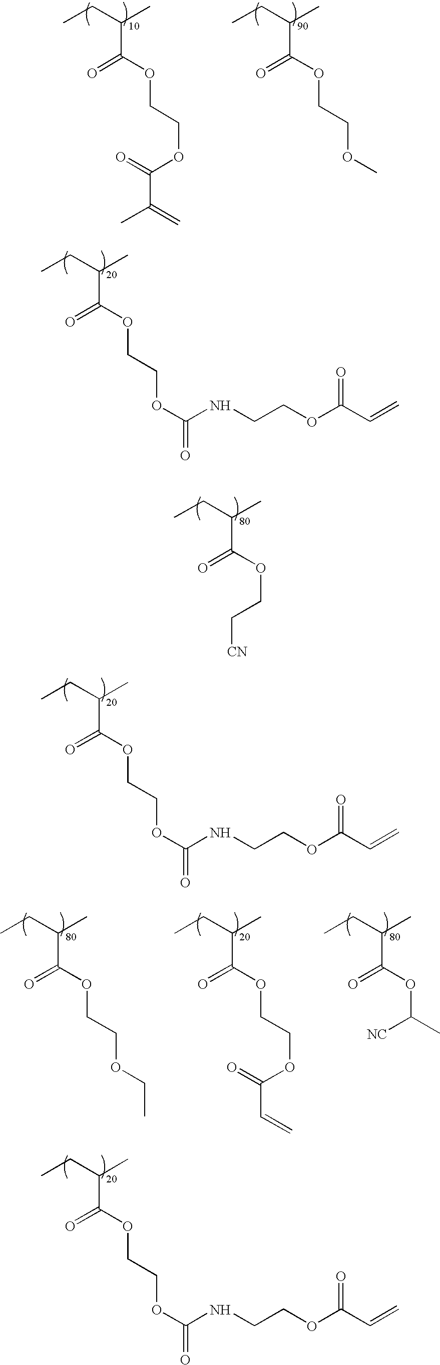

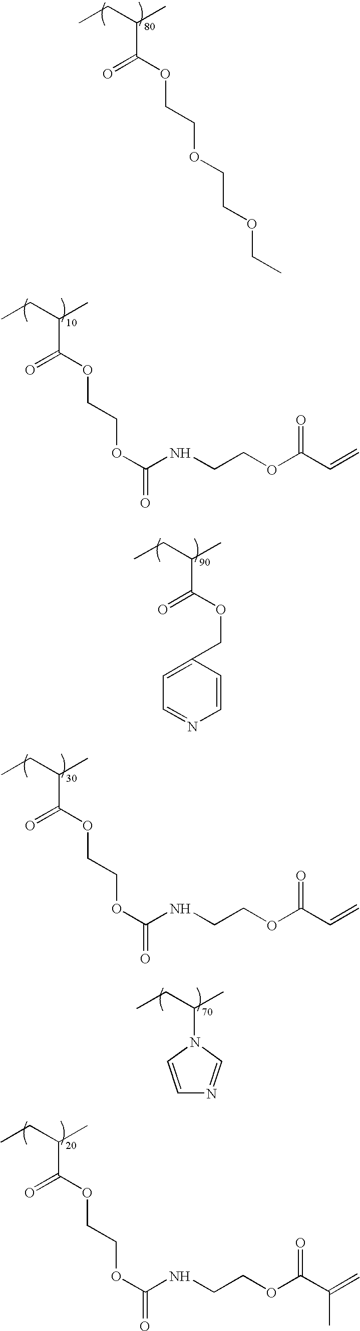

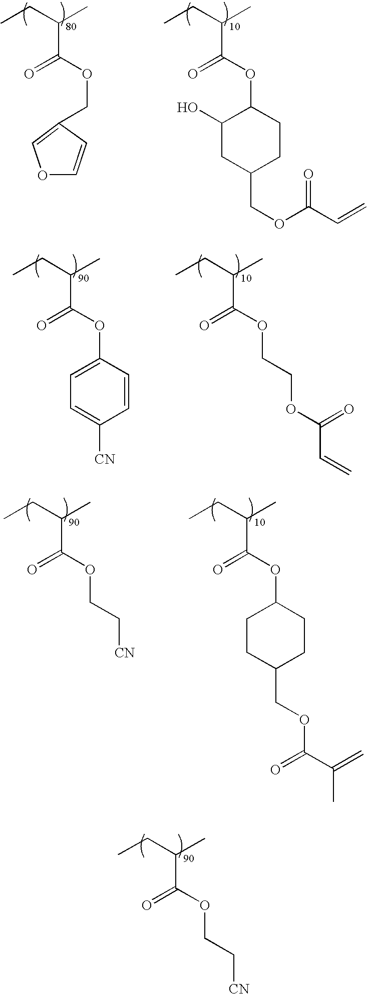

Next, a polymer that has a cyano group and a polymerizable group (hereinafter, referred to as “cyano-group-containing polymerizable polymer” in some cases), which is most preferable embodiment of the specific polymer of the present invention, is described below.

The cyano-group-containing polymerizable polymer in the present invention is a hydrophobic compound, and is preferably, for example, a copolymer that includes a unit represented by the following Formula (1) and a unit represented by the following Formula (2).

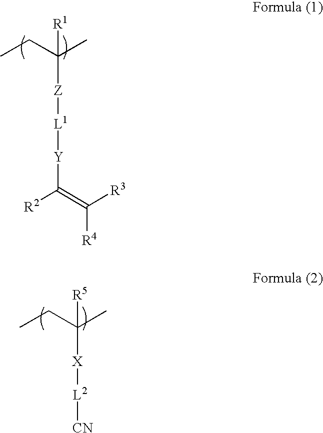

In Formula (1) and Formula (2), R¹ to R⁵ each independently represent a hydrogen atom or a substituted or unsubstituted alkyl group; X, Y, and Z each independently represent a single bond, a substituted or unsubstituted divalent organic group, an ester group, an amido group, or an ether group; and L¹ and L² each independently represent a substituted or unsubstituted divalent organic group.

When any of R¹ to R⁵ represents a substituted or unsubstituted alkyl group, examples of the unsubstituted alkyl group include a methyl group, an ethyl group, a propyl group, and a butyl group, and examples of the substituted alkyl group include a methyl group, an ethyl group, a propyl group, or a butyl group, each of which is substituted with at least one of a methoxy group, a hydroxy group, a chlorine atom, a bromine atom, a fluorine atom, or the like.

R¹ preferably represents a hydrogen atom, a methyl group, or a methyl group substituted with a hydroxy group or a bromine atom.

R² preferably represents a hydrogen atom, a methyl group, or a methyl group substituted with a hydroxy group or a bromine atom.

R³ preferably represents a hydrogen atom.

R⁴ preferably represents a hydrogen atom.

R⁵ preferably represents a hydrogen atom, a methyl group, or a methyl group substituted with a hydroxy group or a bromine atom.

When any of X, Y, and Z represents a substituted or unsubstituted divalent organic group, examples of the divalent organic group include a substituted or unsubstituted aliphatic hydrocarbon group and a substituted or unsubstituted aromatic hydrocarbon group.

Preferable examples of the substituted or unsubstituted aliphatic hydrocarbon group include a methylene group, an ethylene group, a propylene group, and a butylene group, and groups obtained by substituting these groups with at least one of a methoxy group, a hydroxy group, a chlorine atom, a bromine atom, a fluorine atom, or the like.

Preferable examples of the substituted or unsubstituted aromatic hydrocarbon include a unsubstituted phenyl group, and a phenyl group substituted with at least one of a methoxy group, a hydroxy group, a chlorine atom, a bromine atom, a fluorine atom, or the like.

Among these, —(CH₂)ₙ— (n represents an integer of from 1 to 3) is preferable, and —CH₂— is more preferable.

L¹ preferably represents a divalent organic group having a urethane bond or a urea bond, more preferably a divalent organic group having a urethane bond. In particular, the total carbon number of L¹ is preferably from 1 to 9. Here, the total carbon number of L¹ denotes the total number of carbon atoms that are contained in the substituted or unsubstituted divalent organic group represented by L¹.

The structure of L¹ is, more specifically, preferably a structure represented by the following Formula (1-1) or Formula (1-2).

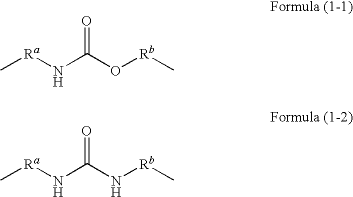

In Formula (1-1) and Formula (1-2), R^{a} and R^{b} each independently represent a divalent organic group composed of at least two atoms selected from the group consisting of carbon atoms, hydrogen atoms, and oxygen atoms, and preferable examples thereof include a methylene group, an ethylene group, a propylene group, a butylene group, an ethylene oxide group, a diethylene oxide group, a triethylene oxide group, a tetraethylene oxide group, a dipropylene oxide group, a tripropylene oxide group, and a tetrapropylene oxide group, each of which may be substituted or unsubstituted.

L² is preferably a straight-chain, branched, or cyclic alkylene group, an aromatic group, or a group that is a combination of these groups. The group that is a combination of the alkylene group and the aromatic group may be a group in which the alkylene group and the aromatic group are linked by at least one of an ether group, an ester group, an amido group, a urethane group, or a urea group. The total carbon number of L² is preferably from 1 to 15, and the divalent organic group represented by L² is preferably unsubstituted. The total carbon number of L² denotes the total number of carbon atoms that are contained in the divalent substituted or unsubstituted organic group represented by L².

Examples of the divalent organic group represented by L² include a methylene group, an ethylene group, a propylene group, a butylene group, and a phenylene group, and groups obtained by substituting these groups with at least one of a methoxy group, a hydroxy group, a chlorine atom, a bromine atom, a fluorine atom or the like, and a group that is a combination of two or more of these groups.

In the cyano-group-containing polymerizable polymer in the present invention, the unit represented by Formula (1) is preferably a unit represented by the following Formula (3).

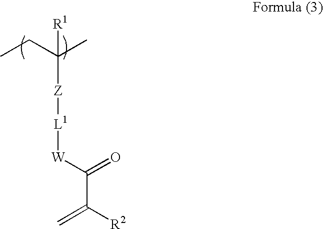

In Formula (3), R¹ and R² each independently represent a hydrogen atom or a substituted or unsubstituted alkyl group; Z represents a single bond, a substituted or unsubstituted divalent organic group, an ester group, an amido group, or an ether group; W represents an oxygen atom or NR (R represents a hydrogen atom or an alkyl group, and preferably represents a hydrogen atom or an unsubstituted alkyl group having 1 to 5 carbon atoms); and L¹ represents a substituted or unsubstituted divalent organic group.

R¹ and R² in Formula (3) have the same definition as R¹ and R² in Formula (1), and have the same preferable definitions as R¹ and R² in Formula (1).

Z in Formula (3) has the same definition as Z in Formula (1), and has the same preferable definitions as Z in Formula (1).

L¹ in Formula (3) has the same definition as L¹ in Formula (1), and has the same preferable definitions as L¹ in Formula (1).

In the cyano-group-containing polymerizable polymer in the present invention, the unit represented by Formula (3) is preferably a unit represented by the following Formula (4).

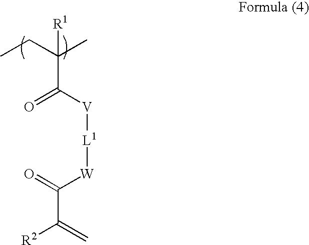

In Formula (4), R¹ and R² each independently represent a hydrogen atom or a substituted or unsubstituted alkyl group; V and W each independently represent an oxygen atom or NR (R represents a hydrogen atom or an alkyl group, and preferably represents a hydrogen atom or a unsubstituted alkyl group having 1 to 5 carbon atoms); and L¹ represents a substituted or unsubstituted divalent organic group.

R¹ and R² in Formula (4) have the same definition as R¹ and R² in Formula (1), and have the same preferable definitions as R¹ and R² in Formula (1).

L¹ in Formula (4) has the same definition as L¹ in Formula (1), and has the same preferable definitions as L¹ in Formula (1).

In Formula (3) and Formula (4), W preferably represents an oxygen atom.

In Formula (3) and Formula (4), L¹ preferably represents an unsubstituted alkylene group or a divalent organic group having a urethane bond or a urea bond, and more preferably represents a divalent organic group having a urethane bond. The total carbon number of the divalent organic group represented by L¹ is preferably from 1 to 9.

Further, in the cyano-group-containing polymerizable polymer in the present invention, the unit represented by Formula (2) is preferably a unit represented by the following Formula (5).

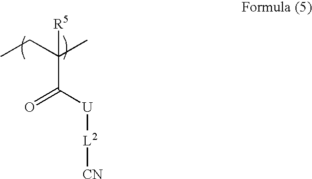

In Formula (5), R⁵ represents a hydrogen atom or a substituted or unsubstituted alkyl group; U represents an oxygen atom or NR′ (R′ represents a hydrogen atom or an alkyl group and preferably represents a hydrogen atom or an unsubstituted alkyl group having 1 to 5 carbon atoms); and L² represents a substituted or unsubstituted divalent organic group.

R⁵ in Formula (5) has the same definition as R¹ and R² in Formula (1), and preferably represents a hydrogen atom.

L² in Formula (5) has the same definition as L² in Formula (2) and preferably represents a straight-chain, branched, or cyclic alkylene group, an aromatic group, or a group that is a combination of these groups.

In Formula (5), the site in L² that links to the cyano group is preferably a divalent organic group having a straight-chain, branched, or cyclic alkylene group, and the total carbon number of this divalent organic group is preferably from 1 to 10.

In another preferred embodiment, the site in L² in Formula (5) that links to the cyano group is preferably a divalent organic group having an aromatic group, and the total carbon number of this divalent organic group is preferably from 6 to 15.

The cyano-group-containing polymerizable polymer in the present invention includes units represented by Formula (1) and units represented by Formula (2), and is a polymer that has a polymerizable group and a cyano group at a side chain or side chains thereof.

The cyano-group-containing polymerizable polymer may be synthesized, for example, as follows.

Examples of the mode of the polymerization reaction used for the synthesis of the cyano-group-containing polymerizable polymer in the present invention include radical polymerization, cation polymerization, and anion polymerization. From the viewpoint of reaction control, it is preferable to use radical polymerization or cation polymerization.

The synthesis method of the cyano-group-containing polymerizable polymer in the present invention varies between (1) a case in which the polymerization mode of the polymer main chain formation is different from the polymerization mode of the polymerizable group to be introduced into a side chain and (2) a case in which the polymerization mode of the polymer main chain formation is the same as the polymerization mode of the polymerizable group to be introduced into a side chain.

When (1) the polymerization mode of the polymer main chain formation is different from the polymerization mode of the polymerizable group to be introduced into a side chain, there are (1-1) an embodiment in which the polymer main chain is formed through cation polymerization and the polymerization mode of the polymerizable group to be introduced into a side chain is radical polymerization and (1-2) an embodiment in which the polymer main chain is formed through radical polymerization and the polymerization mode of the polymerizable group to be introduced into a side chain is cation polymerization.

When (2) the polymerization mode of the polymer main chain formation is the same as the polymerization mode of the polymerizable group to be introduced into a side chain, there are (2-1) an embodiment in which both modes are cation polymerization and (2-2) an embodiment in which both modes are radical polymerization.

Regarding specific synthesis methods, a method described in paragraphs [0196] to in WO 08/050,715 may be applied.

The weight average molecular weight of the cyano-group-containing polymerizable polymer in the present invention is preferably from 1,000 to 700,000 and more preferably from 2,000 to 200,000. Particularly from the viewpoint of polymerization sensitivity, the weight average molecular weight of the cyano-group-containing polymerizable polymer in the present invention is preferably 20,000 or more.

The polymerization degree of the cyano-group-containing polymerizable polymer in the present invention is preferably 10 or more and more preferably 20 or more. The polymerization degree of the cyano-group-containing polymerizable polymer is preferably 7000 or less, more preferably 3,000 or less, still more preferably 2,000 or less, and particularly preferably 1,000 or less.

The preferable ranges of the molecular weight and the polymerization degree described above are also suitable for the other specific polymers used in the present invention than the cyano-group-containing polymerizable polymer.

Specific examples of the cyano-group-containing polymerizable polymer used in the present invention are described below, but they are not limitative.

The weight average molecular weights of these examples are each in the range of from 3,000 to 100,000.

Polymers obtained in embodiment (1-1)

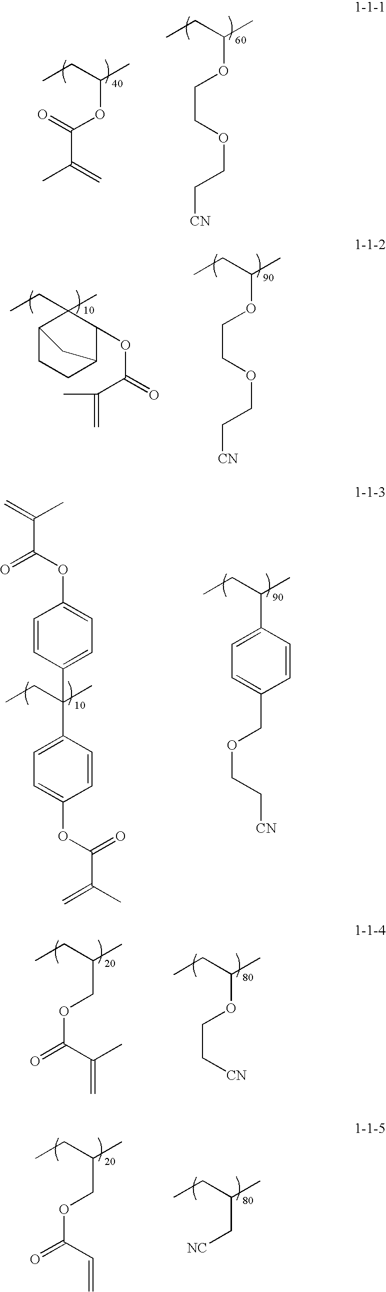

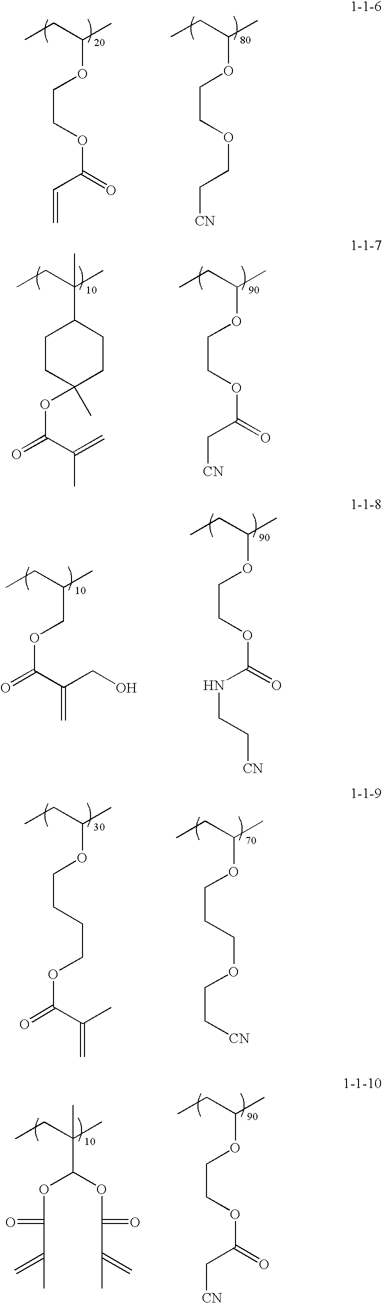

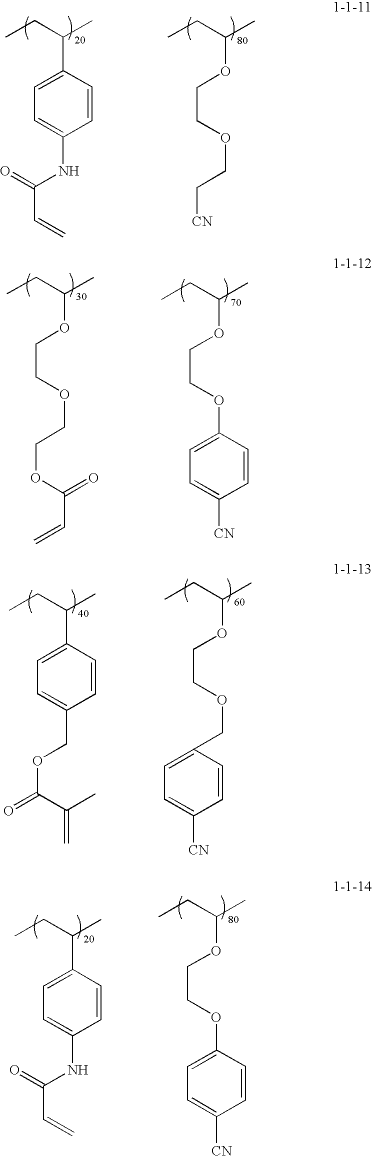

Polymers obtained in embodiment (1-2)

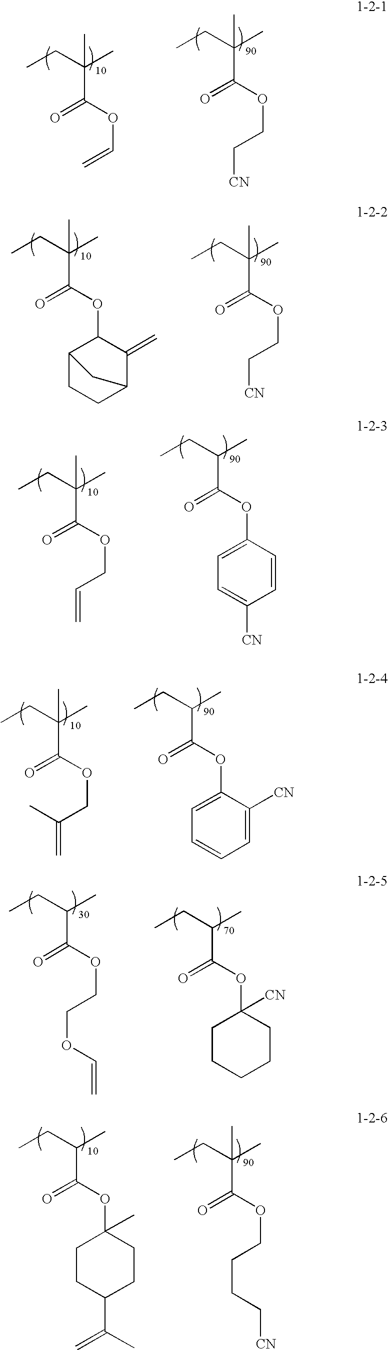

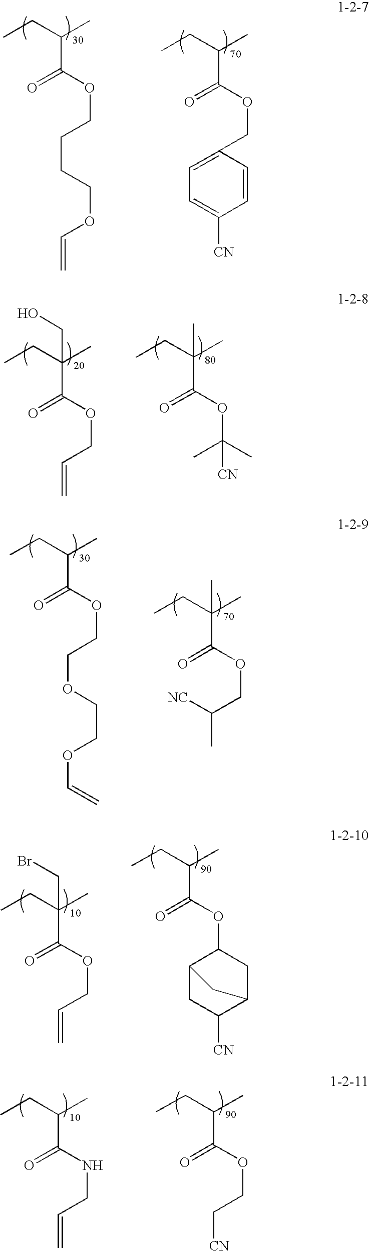

Polymers obtained in embodiment (2-1)

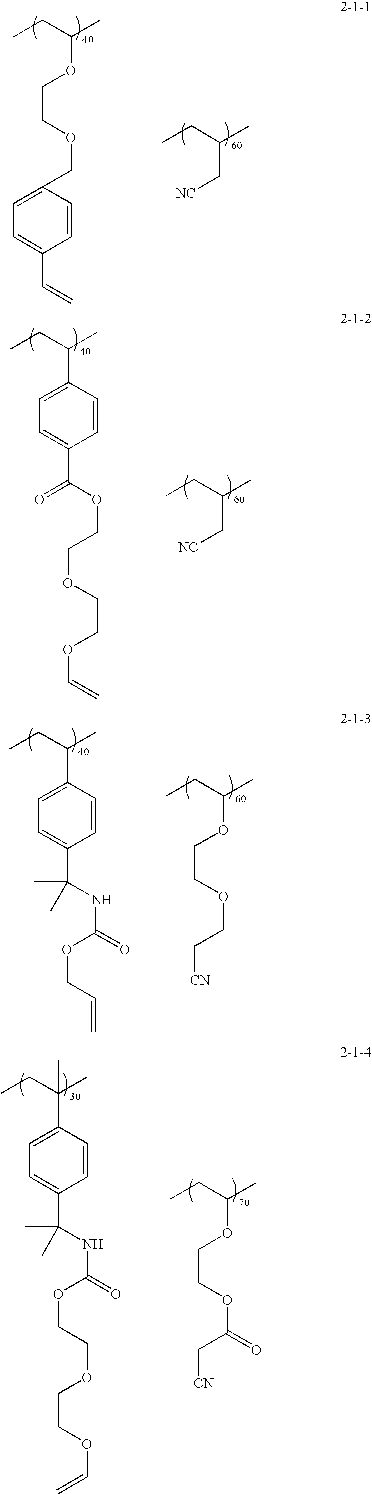

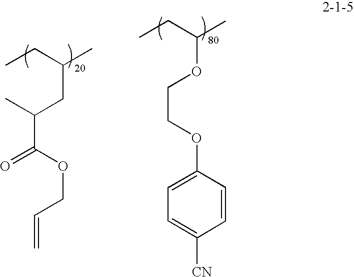

Polymers obtained in embodiment (2-2)

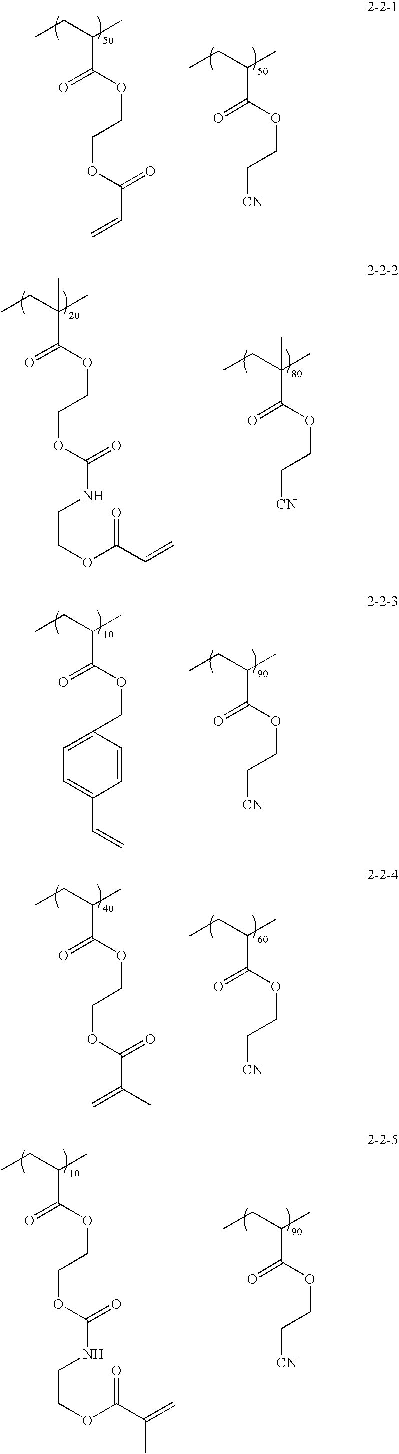

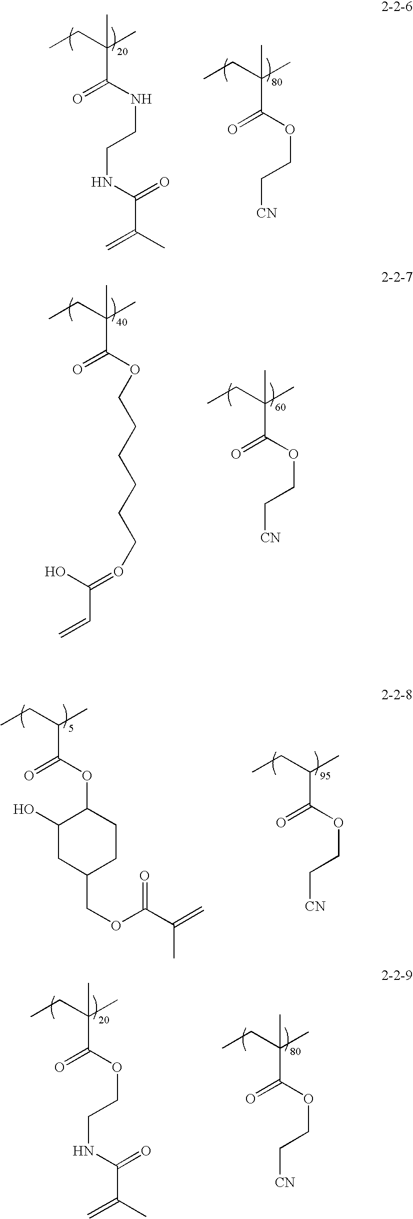

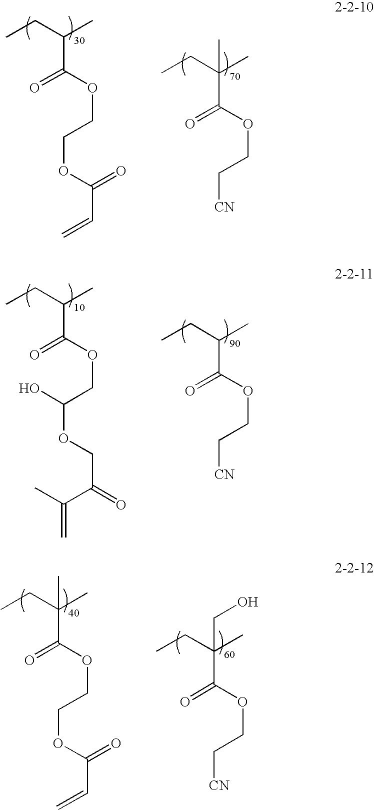

Polymers obtained in embodiment (2-2)

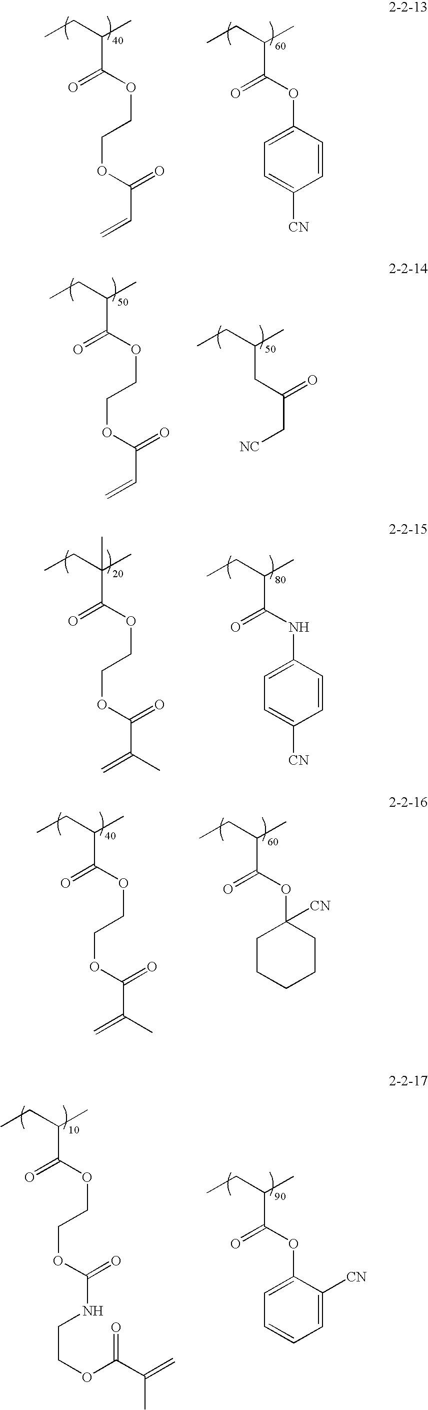

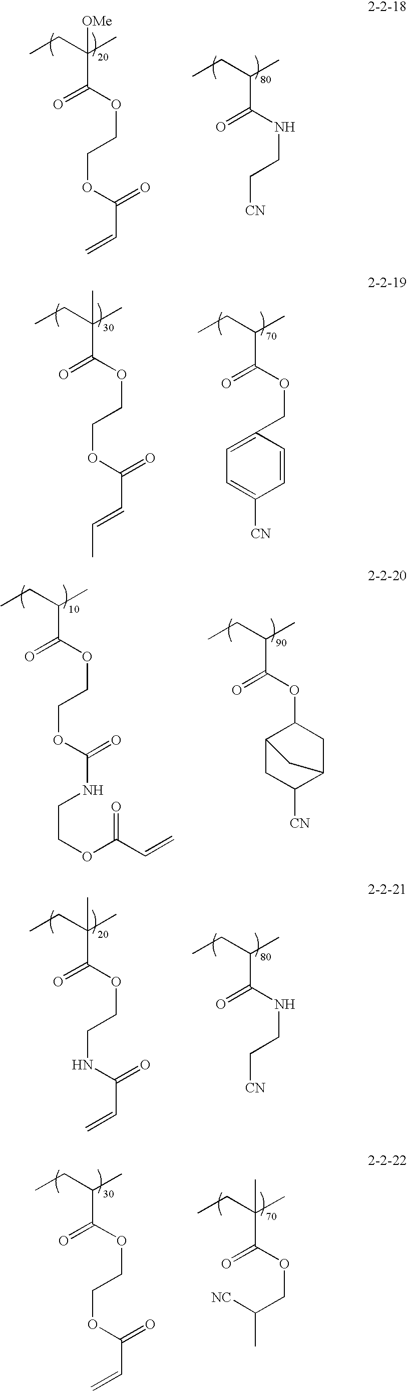

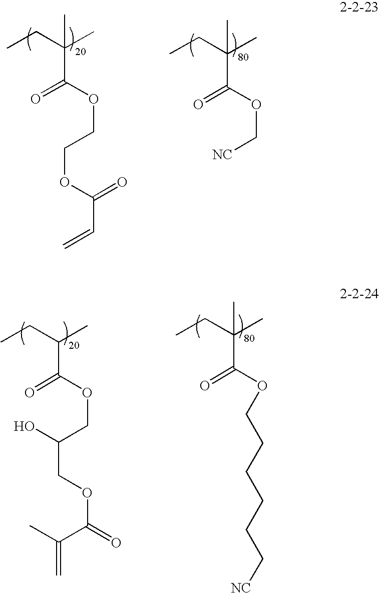

Polymers obtained in embodiment (2-2)

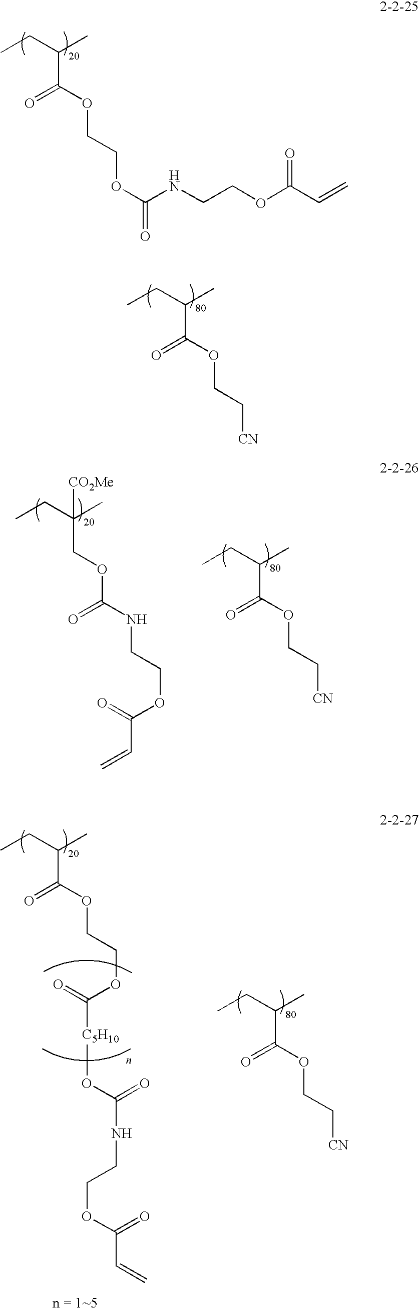

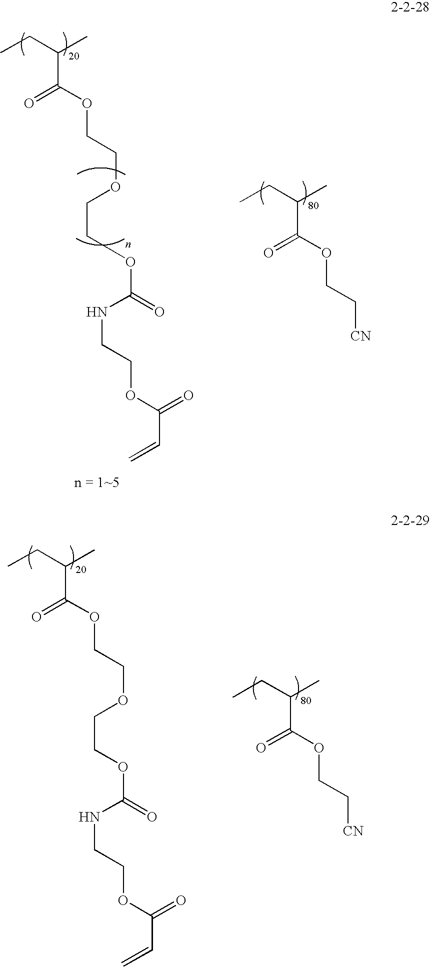

Polymers obtained in embodiment (2-2)

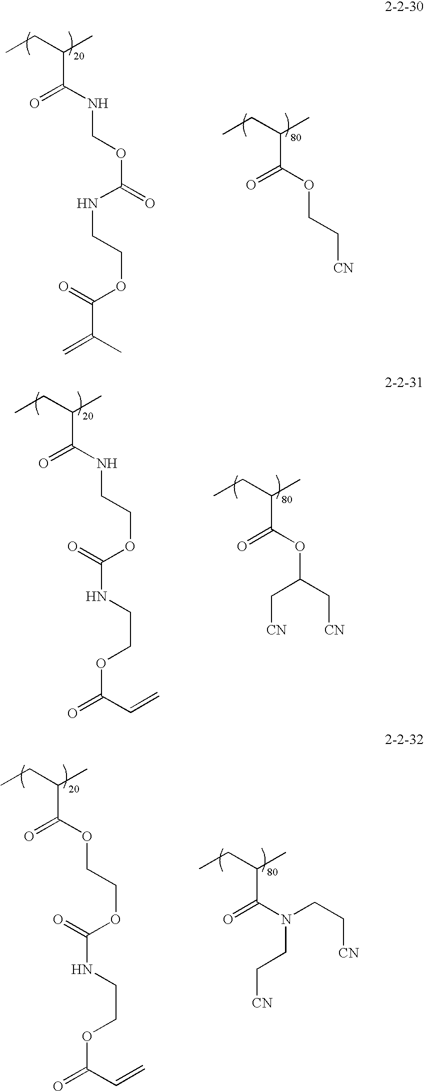

As described above, a liquid composition that includes the specific polymer is preferably used to form the adhesion layer of the present invention.

The solvent used in the liquid composition is not particularly limited as long as the solvent is capable of dissolving the specific polymer, which is the main component of the composition.

Examples of solvents that can be used include: alcohol solvents such as methanol, ethanol, propanol, ethylene glycol, glycerin, and propylene glycol monomethyl ether; acids such as acetic acid; ketone solvents such as acetone, methyl ethyl ketone, and cyclohexanone; an amide solvents such as formamide, dimethylacetoamide, and N-methylpyrrolidone; nitrile solvents such as acetonitrile and propionitrile; an ester solvents such as methyl acetate and ethyl acetate; and carbonate solvents such as dimethyl carbonate and diethyl carbonate.

When the composition includes the cyano-group-containing polymerizable polymer, among the above solvents, the following solvents are preferable: the amide solvents, the ketone solvents, the nitrile solvents, and the carbonate solvents. Specifically, acetone, dimethylacetoamide, methyl ethyl ketone, cyclohexanone, acetonitrile, propionitrile, N-methylpyrrolidone, and dimethyl carbonate are preferable.

When a composition that includes the cyano-group-containing polymerizable polymer is coated, a solvent having a boiling point of from 50° C. to 150° C. is preferable in with a view to facilitate handling. The solvent may be used alone or in a mixture of two or more thereof.

To the liquid composition that includes the specific polymer, one or more selected from a surfactant, a plasticizer, a polymerization inhibitor, a curing agent and/or a curing promoter that promotes curing of a polymerization initiating layer, a rubber component (for example, CTBN), a flame retardant (for example, a phosphorus-containing flame retardant), a diluent, a thixotropic agent, a pigment, a defoaming agent, a leveling agent, a coupling agent, or the like may be added.

Regarding these additives, those described in paragraphs [0125] to [0130] of WO 08/050,715 may be applied.

In the present process, the liquid composition that includes the specific polymer may be applied onto the surface of the adhesion auxiliary layer by an arbitrary method. From the viewpoint of facilitating coating on, particularly, a three-dimensionally-shaped material, it is preferable to use any one of dip coating, spray coating or ink jet coating.

When the coating method as describe above is used, the coating amount in terms of solid content is preferably from 0.1 g/m² to 10 g/m², and particularly preferably from 0.5 g/m² to 5 g/m², from the viewpoints of obtaining a sufficient interaction with the plating catalyst or a precursor thereof and obtaining a coating film with uniform thickness.

In the process (b), after the liquid composition that includes the specific polymer is applied onto the surface of the adhesion auxiliary layer, the solvent in the liquid composition may be removed by drying.

Process (c) of Fixing Adhesion Layer to Adhesion Auxiliary Layer

In the process (c), energy is applied to the adhesion layer formed by the process (b) so as to fix the adhesion layer to the adhesion auxiliary layer.

In this process, the application of energy to the adhesion layer, which has been formed by the process (b), allows active sites generated on the surface of the adhesion auxiliary layer to react with a polymerizable group of the specific polymer, and the reaction between the polymerizable groups of the specific polymer molecules fixes the adhesion layer to the adhesion auxiliary layer.

Application of Energy

Energy may be applied by way of, for example, irradiation of radiation such as light exposure, or heating. In particular, it is preferable to use an energy capable of generating active species in the adhesion auxiliary layer.

The energy application may be performed patternwise. The patternwise application of energy causes only the region of the adhesion layer where the energy has been applied is fixed to the adhesion auxiliary layer.

In the present invention, the light irradiation may be performed using, for example, a UV lamp or visual light. Examples of light sources include a mercury lamp, a metal halide lamp, a xenon lamp, a chemical lamp, and a carbon arc lamp. Examples of the radiation include electron beams, X-rays, ion beams, and far infrared rays. Further examples include g-rays, i-rays, Deep-UV light, and high density energy beams (laser beams).

Examples of the energy application include a method of heating directly in pattern using, for example, a thermal recording head, a method of scanning exposure with a UV laser or a infrared laser, a method of high illumination flash-exposure with a xenon discharge lamp, and a method of exposure with an infrared light lamp.

The time required for applying energy is generally from 10 seconds to 5 hours, although it varies with the curing property of the adhesion layer to be obtained and the light source.

When energy is applied by light exposure, the light exposure power is preferably in the range of from 10 mJ/cm² to 5,000 mJ/cm², and more preferably in the range of from 50 mJ/cm² to 3,000 mJ/cm², in view of facilitating graft polymerization and preventing decomposition of the resulting graft polymer.

When the specific polymer has an average molecular weight of 20,000 or more and a polymerization degree of 200 or more, the reaction easily proceeds with low energy light exposure, so that the decomposition of the fixed adhesion layer can be further suppressed.

In the present invention, energy is applied preferably by laser beam exposure. The laser beam exposure may be performed using, preferably, a UV laser. It is particularly preferable to apply energy patternwise using a UV laser.

Specifically, a portion of the adhesion layer may be irradiated with a UV laser having a wavelength of 256 nm for a scanning time that is regulated to provide an irradiation energy at an irradiated spot of 1,000 mJ, wherein the portion corresponds to a continuous circuit pattern formed by connecting the separate and independent circuit patterns to be finally obtained via current-carrying bridge portions. During the laser irradiation, the laser beams may be focused with a lens and are irradiated onto a portion that requires irradiation, while moving the laser and the adhesion layer relative to each other. The pattern width of the laser irradiation may be controlled by controlling the beam diameter on the surface of the adhesion layer by adjustment of the degree of defocus by adjustment of the focal length of the lens and/or the distance from the adhesion layer. Fine portions of the pattern, which cannot be drawn by a thick beam, may be drawn by forming a thin beam by setting the position of the adhesion layer to match the focus position.

When the decomposition ratio of polymerizable-group moieties is 50% or less after the adhesion layer obtained above is added into a pH12 alkaline solution and stirred for 1 hour, washing with a highly alkaline solution may be performed so as to remove uncured specific polymer.

In the present process, when energy is patternwise applied to the adhesion layer formed by the process (b), the adhesion layer in the region (corresponding to the non-circuit portion) to which energy has not been applied is required to be developed, as described above. Further, when the adhesion auxiliary layer is partly removed with a laser as in the process (g1) described below, the adhesion layer that is applied onto the area where the adhesion auxiliary layer has been removed is required to be developed in the present process (process (c)), which is performed subsequently to the application of the adhesion layer.

For this reason, in the present invention, it is preferable to select an embodiment in which development of the adhesion layer is unnecessary rather than the embodiment described above, from the viewpoint of simplifying the production process.

Process (d) of Applying Plating Catalyst or Precursor Thereof to Adhesion Layer

In the process (d), a plating catalyst or a precursor thereof is applied to the adhesion layer that was fixed on the adhesion auxiliary layer by the process (c). In the present process, the applied plating catalyst or a precursor thereof is adhered (adsorbed) to an interaction group (preferably, a cyano group) of the polymer contained in the adhesion layer by an interaction caused by intermolecular force such as van der Waals force or caused by a coordination bond formed by a lone electron pair.

The plating catalyst or a precursor thereof may be a material that functions as an electroless plating catalyst in the process (e) described below. Namely, the plating catalyst or a precursor thereof used in the present process is an electroless plating catalyst or a precursor thereof.

Electroless Plating Catalyst

As the electroless plating catalyst used in the present invention, any catalyst may be used as long as it serves as an active nucleus when electroless plating is performed. Examples thereof include a metal that has a catalytic activity for an autocatalytic reduction reaction (a metal known to have a lower ionization tendency than Ni and have a capability of electroless plating), more specific examples of which include Pd, Ag, Cu, Ni, Al, Fe, and Co.

Among these, a catalyst that allows polydentate coordination is preferable, and Pd is particularly preferable in view of the number of the types of functional groups that can coordinate thereto and the strength of the catalytic activity.

The electroless plating catalyst may be used in the form of a metal colloid. Generally, the metal colloid can be prepared by reducing metal ions in a solution that contains a charged surfactant or a charged protecting agent. The charge of the metal colloid can be controlled by the surfactant or the protecting agent used.

Electroless Plating Catalyst Precursor

The electroless plating catalyst precursor to be used in the present process is not particularly limited as long as it can be converted to an electroless plating catalyst through chemical reaction. Typical examples thereof include ions of the metals that are described above as examples of electroless plating catalysts. A metal ion that is an electroless plating catalyst precursor is converted, by reduction, into a zero-valent metal that serves as an electroless plating catalyst. In an embodiment, the metal ion that is an electroless plating catalyst precursor is converted into a zero-valent metal by separately-performed reduction reaction after being applied to a resin composition layer but before being immersed in an electroless plating bath. In another embodiment, the metal ion that is an electroless plating catalyst precursor is immersed, as it is, in the electroless plating bath and is converted to a metal (electroless plating catalyst) by an action of a reducing agent contained in the electroless plating bath.

In practice, the metal ion that is an electroless plating catalyst precursor is applied, in the form of a metal salt, onto the resin composition layer. The metal salt to be used is not particularly limited as long as it dissolves in an appropriate solvent and dissociates into a metal ion and a base (anion). Examples thereof include M(NO₃)ₙ, MClₙ, M_{2/n}(SO₄), M_{3/n}(PO₄), and M(OAc)ₙ (M represents an n-valent metal atom and Ac represents an acetyl group). The metal ion formed by dissociation of any of the above metal salts is preferably used. Specific examples of the metal ion include an Ag ion, a Cu ion, an Al ion, a Ni ion, a Co ion, a Fe ion, and a Pd ion. Among these, an ion that allows polydentate coordination is preferable, and Pd is particularly preferable in view of the number of the types of functional groups that can coordinate thereto and the strength of the catalytic activity.

In the process (b), a composition that includes the specific polymer is brought into contact with the adhesion auxiliary layer. In an embodiment, the plating catalyst or a precursor thereof is provided to the adhesion layer by using a method of incorporating the electroless plating catalyst or a precursor thereof into the composition. The composition that includes the specific polymer and the electroless plating catalyst or a precursor thereof is brought into contact with the adhesion auxiliary layer, and then the process (c) is performed, so that an adhesion layer is formed, the adhesion layer including the plating catalyst and a precursor thereof and the polymer that has an interaction group and is chemically and directly bonded to the adhesion auxiliary layer. Use of this method allows the process (b) and the process (d) in the present invention to be performed at the same time.

Plating Catalyst Liquid

When the plating catalyst or a precursor thereof is applied onto the surface of the adhesion layer, it is preferable to use a plating catalyst liquid that includes the plating catalyst or a precursor thereof.

The plating catalyst liquid may include an organic solvent. The organic solvent included in the plating catalyst liquid enhances the permeability of the plating catalyst or a precursor thereof into the adhesion layer, so that the plating catalyst or a precursor thereof may be adsorbed efficiently to the interaction group.

The organic solvent used for the preparation of the plating catalyst liquid is not particularly limited as long as it is capable of penetrating into the adhesion layer. The organic solvent is preferably a water-soluble organic solvent as described below, that is, an organic solvent capable of dissolving uniformly in water at an arbitrary ratio. This is because water is generally used as the main solvent (dispersing medium) of the plating catalyst liquid. Nonetheless, the solvent is not limited to only the water-soluble organic solvent, and an organic solvent that is generally “non-aqueous” may be used if water is used as the main solvent and the organic solvent is dissolved within the solvent content range described below.

Water-Soluble Organic Solvent

The water-soluble organic solvent used in the plating catalyst liquid in the present invention is not particularly limited as long as the solvent mix with water at an arbitrary ratio. Examples of the water-soluble organic solvent include a ketone solvent, an ester solvent, an alcohol solvent, an ether solvent, an amine solvent, a thiol solvent, and a halogenated solvent.

Examples of the ketone solvent include: acetone, 4-hydroxy-4-methyl-2-pentanone, γ-butyrolactone, and hydroxyacetone.

Examples of the ester solvent include: ethyl acetate, 2-(2-ethoxyethoxy)ethyl acetate, ethyleneglycol monomethylether acetate, diethyleneglycol monoethylether acetate, methylcellosolve acetate, 2-hydroxyethyl acrylate, hydroxypropyl acrylate, methyl glycolate, and ethyl glycolate.

Examples of the alcohol solvent include: ethanol, isopropyl alcohol, normalpropyl alcohol, 3-acetyl-1-propanol, 2-(allyloxy)ethanol, 2-aminoethanol, 2-amino-2-methyl-1-propanol, (±)-2-amino-1-propanol, 3-amino-1-propanol, 2-dimethyl aminoethanol, 2,3-epoxy-1-propanol, ethylene glycol, 2-fluoroethanol, diacetone alcohol, 2-methylcyclohexanol, 4-hydroxy-4-methyl-2-pentanone, glycerin, 2,2′,2″-nitrilotriethanol, 2-pyridine methanol, 2,2,3,3-tetrafluoro-1-propanol, 2-(2-aminoethoxy)ethanol, 2-[2-(benzyloxy)ethoxy]ethanol, 2,3-butanediol, 2-butoxyethanol, 2,2′-thiodiethanol, 1,3-butanediol, 1,4-butanediol, 2,3-butanediol, 2-methyl-2,4-pentanediol, 1,3-propanediol, diglycerin, 2,2′-methyliminodiethanol, and 1,2-pentanediol.

Examples of the ether solvent include: bis(2-ethoxyethyl)ether, bis[2-(2-hydroxyethoxy)ethyl]ether, 1,2-bis(2-methoxyethoxy)ethane, bis[2-(2-methoxyethoxy)ethyl]ether, bis(2-methoxyethyl)ether, 2-(2-butoxyethoxy)ethanol, 2-[2-(2-chloroethoxy)ethoxy]ethanol, 2-ethoxyethanol, 2-(2-ethoxyethoxy)ethanol, 2-isobutoxy ethanol, 2-(2-isobutoxyethoxy)ethanol, 2-isopropoxy ethanol, 2-[2-(2-methoxyethoxy)ethoxy]ethanol, 2-(2-methoxyethoxy)ethanol, 1-ethoxy-2-propanol, 1-methoxy-2-propanol, tripropyleneglycol monomethylether, methoxy acetic acid, and 2-methoxy ethanol.

Examples of the glycol solvent include: diethylene glycol, triethylene glycol, ethylene glycol, hexaethylene glycol, propylene glycol, dipropylene glycol, and tripropylene glycol.

Examples of the amine solvent include: N-methyl-2-pyrrolidone and N,N-dimethylformamide.

Examples of the thiol solvent include: mercaptoacetic acid and 2-mercaptoethanol. Examples of the halogenated solvent include: 3-bromobenzyl alcohol, 2-chloroethanol, and 3-chloro-1,2-propanediol.

Further examples of water-soluble organic solvents that may be used further include the solvents described in the following Table 1.

TABLE 1

| Acrylic acid | 2-(Dimethylamino) ethyl | Acetyl methyl carbinol |
|---|---|---|
| | acrylate | |
| 1-Amino-4-methyl | 3-Aldehyde pyridine | Isolactic acid |
| piperazine | | |
| Aluminum ethylacetoacetate diisopropylate (water-soluble) | | Ethyl glycol |
| Ethylene glycol monobutyl | Ethylene chlorohydrin | N-ethyl morpholine |
| ether | | |
| Ethylene diamine | 3-Ethoxy propylamine | Formic acid (at least 86%) |
| Isoamyl formate | Acetic acid | 1,4-Diaminobutane |
| 1,2-Diaminopropane | 1,3-Diaminopropane | 3-Diethylaminopropyl |
| | | amine |
| N,N-diethylethanolamine | Cyclohexyl amine | N,N-dimethylacetoamide |
| Di-n-butoxy-bis(triethanol aminato) titanium | | Dimethylaminopropyl |
| | | amine |
| 2-Dimethylaminoacetoaldehyde dimethylacetal | | N,N-dimethylethanol |
| | | amine |
| 2,5-Dimethyl pyrazine | Insect flower (for grain | Hydrated hydrazine (79% |
| | storage)(emulsion) | or lower) |
| Sodium alcoholate (liquid) | Teteramethyl-1,3-diamino | Sodium methoxide |
| | propane | |
| 1,1,3-Trihydrotetrafluoro | Ethyl lactate | Methyl lactate |
| propanol | | |
| α-Picoline | β-Picoline | γ-Picoline |
| Hydrazine (79% or lower) | Propionic acid | Propylene chlorohydrin |
| Benzyl aminopurine (3% | Trimethyl borate | Methylaminopropyl amine |
| emulsion) | | |
| N-methyl piperazine | 2-Methyl pyrazine | 3-Methoxypropyl amine |
| 2-Mercaptoethanol | Morpholine | Diethylene triamine |
| N,N-dimethyl acrylamide | Dimethylaminopropyl | Dimethyl sulfoxide |
| | methacrylamide | |
| N,N-dimethylaminopropyl | | (−)-D-diisopropyl tartarate |
| acrylamide | | |
| Hydrated hydrazine (at least | Sulfolane (anhydride is in a | Thioglycolic acid |
| 80%) | solid and non-hazardous | |
| | chemical) | |
| Thiodiglycol | Tetraethylene pentamine | n-Tetradecane |
| N,N,N′,N′-tetramethyl-1,6-hexamethylene diamine | | Triethyl phosphate (TEP) |
| Triethylene glycol | Triethylene tetramine | Trimethyl phosphate |
| d-Valerolactone | Bisaminopropyl piperazine | Hydrazine (at least 80%) |
| 2-Hydroxyethyl acrylate | 2-Hydroxyethyl aminopropyl | Hydroxyethyl piperazine |
| | amine | |
| 4-Hydroxy-2-butanone | Vinyl tris(β-methoxyethoxy) | 2-Pyridine methanol |
| | silane | |
| 3-Pyridine methanol | 4-Pyridine methanol | Pyruvic acid |
| Phenetylamine | Formamide | 1,3-Butanediol |
| 1,4-Butanediol | Butyl diglycol | γ-Butyrolactone |
| Furfuryl alcohol | Hexylene glycol | Benzylamine |
| Pentaethylene hexamine | Polyethyleneglycol diglycidyl ether (n ≈ 13 or less) | |
| Polypropyleneglycol diglycidyl ether (n ≈ 11 or less) | | Methacrylic acid |
| 2-Hydroxyethyl methacrylate | Methyliminobispropyl amine | N-methylethanolamine |
| N-methyl-N,N-diethanolamine | 3-Methyl-3-methoxybutyl | β-Mercaptopropionic acid |
| | acetate | |
| Ethylene glycol monoacetate | | |

The content of the water-soluble organic solvent in the plating catalyst liquid in the present invention is preferably from 0.1% to 40% by mass, and more preferably from 5% to 40% by mass, with respect to the total amount of the plating catalyst liquid, from the viewpoint of the permeability into the adhesion layer described below.

From the viewpoint of avoiding oxidation by the catalyst metal, the plating catalyst liquid is preferably free from alcohol; the absence of alcohol is preferable in view of the liquid storability of the plating catalyst liquid. For this reason, preferable examples of the water-soluble organic solvent in the present invention include ketone solvents, ester solvents, and ether solvents. More specifically, preferable examples of the water-soluble organic solvent include acetone, dimethyl carbonate, ethyleneglycol dimethyl ether, 2-(2-ethoxyethoxy)ethyl acetate, 1-acetoxy-2-methoxyethane, bis(2-ethoxyethyl)ether (also known as: diethyleneglycol diethyl ether), 1,2-bis(2-methoxyethoxy)ethane, bis[2-(2-methoxyethoxy)ethyl]ether, and bis(2-methoxyethyl)ether (also known as: diethyleneglycol dimethylether).

The plating catalyst liquid may include, in addition to the plating catalyst or a precursor thereof, one or more other additives in accordance with objectives as long as the effect of the present invention is not impaired.

Examples of other additives include those described below.

Examples of additives include acids (including inorganic acids such as hydrochloric acid and nitric acid and organic acids such as acetic acid and citric acid), swelling agents (including organic compounds such as ketones, aldehydes, ethers, and esters), and surfactants (including anionic, cationic, amphoteric, and nonionic surfactants, each of which may be low-molecular or high-molecular).

From the viewpoint of allowing sufficient interaction with interaction groups in the adhesion layer, the concentration of metal in the plating catalyst liquid or the metal ion concentration in the plating catalyst liquid is preferably in the range of from 0.001% to 50% by mass, and more preferably from 0.005% to 30% by mass. The contact time is preferably from about 30 seconds to about 24 hours, and more preferably from about 1 minute to about 1 hour.

Process (e) of Forming First Metal Film by Electroless Plating

In the process (e), the adhesion layer to which the plating catalyst or a precursor thereof was applied by the process (d) is subjected to electroless plating so as to form a first metal film.

The electroless plating performed in the present process is described below.

Electroless Plating

Electroless plating is an operation whereby metal is deposited, through a chemical reaction, using a solution in which a metal ion to be deposited as plating is dissolved.

In the present process, electroless plating is performed by, for example, washing the substrate, to which an electroless plating catalyst has been applied, with water to remove excess electroless plating catalyst (metal), and then immersing the substrate in an electroless plating bath. Here, the “substrate” refers to a layered structure including the base board, the adhesion auxiliary layer, and the adhesion layer, and optionally further including the first metal film formed by electroless plating and/or the second metal film formed by electroplating; the same applies hereinafter. The electroless plating bath to be used may be a generally known electroless plating bath.

When a substrate to which a precursor of the electroless plating catalyst has been applied and in which the adhesion layer adsorbs or impregnated with the precursor of the electroless plating catalyst is immersed in an electroless plating bath, the substrate may be washed with water to remove excess precursor (for example, metal salt) before the immersing in the electroless plating bath. In this case, reduction of the precursor of the plating catalyst and electroless plating that follows the reduction proceeds in the electroless plating bath. Similarly to the above, the electroless plating bath to be used may be a generally known electroless plating bath.

The manner in which the precursor of the electroless plating catalyst is reduced is not limited to the method using the electroless plating liquid as described above. In an alternative embodiment, a catalyst activating solution (a reducing solution) is prepared, and the reducing of the precursor of the electroless plating catalyst using the catalyst activating solution is performed as a separate process prior to the electroless plating.

The catalyst activating solution is a solution in which a reducing agent capable of reducing the precursor (typically, metal ion) of the electroless plating catalyst to a zero-valent metal is dissolved in an amount of from 0.1% to 50% by mass, preferably from 1% to 30% by mass. Examples of reducing agents that may be used include boron-containing reducing agents such as sodium boron hydride and dimethylamine borane, and other reducing agents such as formaldehyde and hypophosphorous acid.

The composition of a general electroless plating bath includes, besides the solvent, mainly (1) a metal ion for plating, (2) a reducing agent, and (3) an additive (stabilizer) that improves the stability of the metal ion. Besides these, the plating bath may further include known additives such as plating bath stabilizers.

The selection of the kind of the organic solvent to be used in the plating bath and determination of the content thereof may be made appropriately in accordance with the affinity of the organic solvent to the adhesion layer. For example, when the adhesion layer is composed of a specific polymer that is a hydrophobic compound, the adhesion layer is hydrophobic, so that use of an organic solvent having a high affinity to the hydrophobic adhesion layer is preferable.

As the metal that is used in the electroless plating bath, copper, tin, lead, nickel, gold, palladium, and rhodium are known, and among these, copper and gold are particularly preferable in consideration of conductivity.

An optimum reducing agent and an optimum additive may vary with the kind of the metal. For example, a copper electroless plating bath may include CuSO₄ as a copper salt, HCHO as a reducing agent, and additives such as trialkanolamines and chelating agents such as EDTA and Rochelle salt, which are copper ion stabilizers. A plating bath used for CoNiP electroless plating may include cobalt sulfate and nickel sulfate as salts of the metals, sodium hypophosphite as a reducing agent, and sodium malonate, sodium malate, and sodium succinate as complexing agents. A palladium electroless plating bath may include (Pd(NH₃)₄)Cl₂ as a metal salt, NH₃ and H₂NNH₂ as reducing agents, and EDTA as a stabilizer. These plating baths may include other components than those described above.

The thickness of the resulting plating film formed by electroless plating may be controlled by at least one of the metal ion concentration in the plating bath, the immersion time in the plating bath, the temperature of the plating bath, or the like. From the viewpoint of electrical conductivity, the thickness of the plating film is preferably from 0.2 μm to 2.0 μm, more preferably from 0.3 μm to 1.5 μm, and still more preferably from 0.5 μm to 1.0 μm.

The immersion time, which is the length of time during which the substrate to which the electroless plating catalyst or a precursor thereof has been applied is immersed in the plating bath, is preferably from about 1 minute to about 6 hours, and more preferably from about 1 minute to about 3 hours.

The electroless plating film obtained as described above was subjected to cross-section observation by SEM. It was confirmed that fine particles made of the electroless plating catalyst and the plating metal were densely dispersed in the adhesion layer and the plating metal was deposited on the adhesion layer. Since interface between the adhesion layer and the plating film is in a hybrid state of the polymer and the fine particles, the adhesion of the plating film to the adhesion layer is excellent even when the interface between the substrate (organic material) and the inorganic material (the catalyst metal or the plating metal) is smooth (for example, the unevenness is 500 nm or less).

Process (f) of Performing Electroplating

In the process (f), electroplating is performed using the first metal film formed by the process (e). The electroplating performed in the present process is described below.

Electroplating

In the present process, electroplating is performed using the first metal film formed by the process (e) as an electrode.

The electroplating enables easy formation of a metal film having an arbitrary thickness.

As the electroplating method used in the present invention, conventionally known methods may be used. Examples of metals that may be used in the electroplating in the present invention include copper, chromium, lead, nickel, gold, silver, tin, and zinc. From the viewpoint of electrical conductivity, copper, gold, and silver are preferable, and copper is more preferable.

The thickness of the final metal film obtained by electroplating varies with the applications of the circuit board, and can be controlled by adjusting the concentration of the metal included in the plating bath, the current density, and the like. When the circuit board is used in, for example, a general electrical wiring, the thickness of the final metal film is preferably 0.5 μm or more, and more preferably 3 μm or more, from the viewpoint of electrical conductivity.

In the present invention, the adhesion between the metal film and the adhesion layer is further enhanced by the metal or metal salt derived from the plating catalyst or precursor thereof and/or the metal deposited in the adhesion layer by electroless plating being present in the form of a fractal fine structure in the adhesion layer.

Regarding the amount of the metal contained in the adhesion layer, further stronger adhesion is achieved when the following condition A is satisfied.

Condition A: when the cross-section of the substrate is photographed using a metallographic microscope, the ratio of the metal in the region extending from the outermost surface of the adhesion layer to the depth of 0.5 μm is from 5% to 50% in terms of area ratio and the arithmetic average roughness R^{a} (according to JIS B0633-2001, which is incorporated herein by reference) of the interface between the adhesion layer and metal is from 0.05 μm to 0.5 μm.

Process (g) of Partly Removing Area Corresponding to Non-Circuit Portion

In the process (g), the area corresponding to a non-circuit portion in any of the adhesion auxiliary layer prior to the process (b), the adhesion layer fixed to the adhesion auxiliary layer prior to the process (d), the adhesion layer having had the plating catalyst or a precursor thereof applied thereto prior to the process (e), and the first metal film prior to the process (f) is partly removed by irradiating a laser beam.

In the present process, any of the adhesion auxiliary layer, the adhesion layer, or the first metal film after the process (a), (c), (d), or (e) but before the next process is partly removed using a laser.

In this way, the non-circuit portion is removed using a laser, whereby occurrence of the residues between circuits is suppressed.

In the present process, two or more processes selected from (g1) to (g5) described below may be used together during fabrication of the circuit board, thereby further suppressing the occurrence of the residues between circuits.

In the present process, the portion that is removed using a laser is an area corresponding to the non-circuit portion, and is preferably the entire area except a continuous circuit pattern formed by connecting the separate and independent circuits to be finally obtained via current-carrying bridge portions. By leaving the continuous circuit pattern, electroplating in the process (f) can be performed more easily.

In the present process, if the area corresponding to the non-circuit portion in the adhesion auxiliary layer formed by the process (a) is partly removed by irradiating a laser beam (this process is hereinafter referred to as a process (g1) in some cases), the following procedure may be taken.

In an embodiment of the process (g1), after the process (a) but before the process (b), a laser beam is irradiated to the adhesion auxiliary layer formed on the surface of the insulating base board. During the laser irradiation, the laser beam is focused with a lens, and the laser beam and the base board having the adhesion auxiliary layer formed thereon are moved relative to each other, such that the laser irradiation is performed on the whole of the portion at which the laser irradiation is required (for example, the entire area except a continuous circuit pattern formed by connecting the separate and independent circuits to be finally obtained via current-carrying bridge portions).

The pattern width of the laser irradiation may be controlled by controlling the beam diameter on the surface of the adhesion auxiliary layer by adjustment of the degree of defocus by adjustment of the focal length of the lens or the distance from the adhesion auxiliary layer. Fine portions of the pattern, which cannot be drawn by a thick beam, may be drawn by forming a thin beam by setting the position of the adhesion auxiliary layer to match the focus position.

The operation speed or the laser emission intensity may be regulated to provide a laser power of from 0.1 J/cm² to 1.0 J/cm².

As a result of the laser irradiation in the above manner, most of the adhesion auxiliary layer in the laser-irradiated portion is removed.

After the laser irradiation, the base board having the adhesion auxiliary layer formed thereon may be washed with an organic solvent such as ethanol, acetone, toluene, or methyl ethyl ketone, thereby removing the adhesion auxiliary layer that remains in a small amount in the laser-irradiated portion together with a surface portion of the insulating base board that has been altered by the laser irradiation. During the washing, use of ultrasonic cleaning produces an increased effect. In an embodiment, the adhesion auxiliary layer that remains in a small amount in the laser-irradiated portion and the surface portion of the insulating base board that has been altered by the laser irradiation may be removed by wiping with an unwoven cloth that is impregnated with a solvent.

In the present process, if the area corresponding to the non-circuit portion in the adhesion layer that was fixed to the adhesion auxiliary layer by the process (c) is partly removed by irradiating a laser beam (this process is hereinafter referred to as a process (g2) in some cases), the following process may be taken.

In an embodiment of the (g2) process, after the process (c) but before the process (d), a laser beam is irradiated to the adhesion layer fixed to the adhesion auxiliary layer. During the laser irradiation, the laser beam is focused with a lens, and the laser beam and the base board having the adhesion layer formed thereof are moved relative to each other, such that the laser irradiation is performed on the whole of the portion at which the laser irradiation is required (for example, the entire area except a continuous circuit pattern formed by connecting the separate and independent circuits to be finally obtained via current-carrying bridge portions).

The pattern width of the laser irradiation may be controlled by controlling the beam diameter on the surface of the adhesion layer by adjustment of the degree of defocus by adjustment of the focal length of the lens or the distance from the adhesion layer. Fine portions of the pattern, which cannot be drawn by a thick beam, may be drawn by forming a thin beam by setting the position of the adhesion layer to match the focus position.

The operation speed or the laser emission intensity may be regulated to provide a laser power of from 0.1 J/cm² to 1.0 J/cm².

As a result of the laser irradiation in the above manner, most of the adhesion layer in the laser-irradiated portion is removed. When removing the adhesion layer, the adhesion auxiliary layer, which is an underlayer of the adhesion layer, may be removed together. The removing of the adhesion layer and the adhesion auxiliary layer together may be achieved by increasing the laser power to be higher than the range described above.

After the laser irradiation, the base board having the adhesion layer formed thereon may be washed with an organic solvent such as ethanol, acetone, toluene, or methyl ethyl ketone, thereby removing the adhesion layer that remains in a small amount in the laser-irradiated portion together with a surface portion of the adhesion auxiliary layer that has been altered by the laser irradiation. During the washing, use of ultrasonic cleaning produces an increased effect. In an embodiment, the adhesion layer that remains in a small amount in the laser-irradiated portion together with a surface portion of the adhesion auxiliary layer that has been altered by the laser irradiation may be removed by wiping with an unwoven cloth impregnated with a solvent.

In the present process, if the area that corresponds to the non-circuit portion in the adhesion layer to which the plating catalyst or a precursor thereof has been applied by the process (d) is partly removed by irradiating a laser beam (this process if hereinafter referred to as a process (g3) in some cases), the following process may be taken.

In an embodiment of the process (g3), after the process (d) but before the process (e), a laser beam is irradiated to the adhesion layer to which the plating catalyst or a precursor thereof has been applied. During the laser irradiation, the laser beam is focused with a lens, and the laser beam and the base board having the adhesion layer formed thereon are moved relative to each other, such that the laser irradiation is performed on the whole of the portion at which the laser irradiation is required (for example, the entire area except a continuous circuit pattern formed by connecting the separate and independent circuits to be finally obtained via current-carrying bridge portions).

The pattern width of the laser irradiation may be controlled by controlling the beam diameter on the surface of the adhesion layer by adjustment of the degree of defocus by adjustment of the focal length of the lens or the distance from the adhesion layer. Fine portions of the pattern, which cannot be drawn by a thick beam, may be drawn by forming a thin beam by setting the position of the adhesion layer to match the focus position.

The operation speed or the laser emission intensity may be regulated to provide a laser power of from 0.1 J/cm² to 1.0 J/cm².

As a result of the laser irradiation in the above manner, in the laser-irradiated portion, most of the adhesion layer to which the plating catalyst or a precursor thereof has been applied is removed. When removing the adhesion layer to which the plating catalyst or a precursor thereof has been applied, the adhesion auxiliary layer, which is an underlayer of the adhesion layer, may be removed together. The removing of the adhesion layer and the adhesion auxiliary layer together may be achieved by increasing the laser power to be higher than the range described above.

After the laser irradiation, the base board having the adhesion layer formed thereon may be washed with an organic solvent such as ethanol, acetone, toluene, or methyl ethyl ketone, thereby removing the adhesion layer that remains in a small amount in the laser-irradiated portion together with a surface portion of the adhesion auxiliary layer that has been altered by the laser irradiation. During the washing, use of ultrasonic cleaning produces an increased effect. In an embodiment, the adhesion layer that remains in a small amount in the laser-irradiated portion and the surface portion of the adhesion auxiliary layer that has been altered by the laser irradiation may be removed by wiping with an unwoven cloth impregnated with a solvent.

In the present process, if the area corresponding to the non-circuit portion in the first metal film formed by the process (e) is partly removed by irradiating a laser beam (this process is hereinafter referred to as a process (g4) in some cases), the following process may be taken.

In an embodiment of the (g4) process, after the process (e) but before the process (f), a laser beam is irradiated to the first metal film. The laser irradiation may be performed using a YAG laser or the like. The laser irradiation may be conducted in such a manner that the laser irradiation is performed on the whole of the portion at which the laser irradiation is required (for example, the entire area except a continuous circuit pattern formed by connecting the separate and independent circuits to be finally obtained via current-carrying bridge portions). The pattern width of the laser irradiation may be controlled by controlling the beam diameter on the surface of the first metal film (adhesion layer) by adjustment of the degree of defocus by adjustment of the focal length of the lens or the distance from the first metal film (adhesion layer). Fine portions of the pattern, which cannot be drawn by a thick beam, may be drawn by forming a thin beam by setting the position of the first metal film (adhesion layer) to match the focus position. The laser irradiation energy is preferably adjusted to be from 10 μJ/pulse to 300 μJ/pulse.

As a result of the laser irradiation in the above manner, most of the first metal film in the laser-irradiated portion is removed. Removal of the first metal film is further ensured by setting the condition of the laser irradiation in such a manner that a thin surface portion of the adhesion layer is removed together with the first metal film. When removing the first metal film, the underlying adhesion layer and, optionally, the adhesion auxiliary layer may be removed together with the first metal film. The removing of the adhesion layer and, optionally, the adhesion auxiliary layer together may be achieved by increasing the laser power to be higher than the range described above.

After the laser irradiation, the base board having the first metal film formed thereon may be washed with ethanol, thereby removing the first metal film that remains in a small amount in the laser-irradiated portion together with a surface portion of the adhesion layer that has been altered by the laser irradiation. During the washing, use of ultrasonic cleaning produces an increased effect.

An embodiment of a process of partly removing, by irradiating a laser beam, an area corresponding to a non-circuit portion in the first metal film formed by the process (e) is the following process (hereinafter referred to as a process (g5) in some cases).

In the process (g5), the first metal film formed by the process (e) that is already patterned is further partly removed by irradiating a laser beam.

Examples of the patterned first metal film include patterned first metal films that are obtained as follows.

Method (1): the adhesion layer is formed in pattern, and the adhesion layer is subjected to the processes (d) and (e) to form a patterned first metal film.

Method (2): the first metal film is formed on an entire surface of the substrate by the process (e), and this first metal film is processed to become patterned.

In the method (1), the patterned adhesion layer may be formed by any of the following: (1-1) applying energy patternwise in the process (c); (1-2) partly removing, by irradiating a laser beam in the present process (i.e., the process (g)), the adhesion auxiliary layer formed by the process (a), and then forming the adhesion layer by the process (c); or (1-3) partly removing, by irradiating a laser beam in the present process (i.e., the process (g)), either of (i) the adhesion layer fixed on the adhesion auxiliary layer by the process (c) or (ii) the adhesion layer to which the plating catalyst or a precursor thereof was applied by the process (d).

In the method (2), the patterned first metal film may be formed in the present process (i.e., the process (g)) by any of the following: (i) partly removing, by irradiating a laser beam, the first metal film formed by the process (e), or (ii) patterning, by using a resist, the first metal film formed by the process (e).

A method such as the process (f) described below may be used as the method of patterning, by using a resist, the first metal film formed by the process (e).

As described above, the two types of embodiments of the present process (process (g)) may be used in combination when a circuit board is fabricated.

The process (g5) may be, for example, the process described below. For example, after forming a first metal film that is in the form of a continuous circuit pattern formed by connecting the separate and independent circuit patterns to be finally obtained via current-carrying bridge portions (a patterned first metal film) according to the processes described above, a process of partly removing, by irradiating a laser beam, only the current-carrying bridge portions of the first metal film forming a circuit pattern may be performed.

If the laser irradiation in the present process is performed on the first metal film formed by the process (e), after the laser irradiation and cleaning are performed, a treatment of completely removing the plating catalyst or a metal derived from the precursor of the plating catalyst that is adhered to the adhesion layer exposed at the laser-irradiated portion may be performed.

As a result of this treatment, metal does not remain in the laser-irradiated portion. Therefore, reliability of insulation between the circuits is excellent. Further, since a second metal film does not deposit on the non-circuit portion even when a highly-active electroplating liquid is used in the process (f), a circuit board with a high accuracy may be fabricated efficiently.

Specifically, examples of the treatment include immersion in an acidic liquid such as sulfuric acid or nitric acid or in a commercial etching liquid using such an acidic liquid, and washing by showering of any of these liquids.

In an embodiment, the irradiation energy of the laser irradiation on the first metal film formed by the process (e) is adjusted to be from 5 J/cm² to 50 J/cm² so as to remove the adhesion layer that includes the plating catalyst or a precursor thereof. In this embodiment, the plating catalyst or a precursor thereof left in deep recess portions of the adhesion layer may be completely removed, thereby increasing the reliability of the insulation between circuits and providing circuits having high accuracy.

In the present process, the portion that is removed by irradiating a laser beam may be limited to a relatively small area including a region around the contour of the continuous circuit pattern. In this case, electric current may be supplied only to the first metal film that corresponds to the continuous circuit pattern during the electroplating performed in the process (f), thereby allowing the second metal film formed by the electroplating of the process (f) to grow only on the first metal film to which the electric current is supplied and thereby increasing the thickness of the circuit.

When this method is employed, the first metal film left in regions other than the continuous circuit pattern can be removed, together with the current-carrying bridge portions of the continuous circuit pattern, in a manner similar to the method described in the explanation of the process (f) described below. As a result, separate and independent circuits are obtained.

When such a method is used, the laser irradiation area is decreased, as a result of which the process (g) may be completed in a shorter time and circuit boards may be fabricated efficiently.

Besides the method of using an organic solvent as described above, examples of the method of cleaning after the laser irradiation further include various methods as described below.

For example, as a first example, plasma cleaning may be used for the cleaning. The plasma cleaning includes, for example, mounting the substrate after the laser irradiation on a discharge electrode in a vacuum chamber, and applying a 13.56 MHz radio-frequency discharge at a power of from 0.5 W/cm² to 5 W/cm² between the discharge electron and an earth electrode so as to generate a plasma, and the plasma is used for the cleaning In the vacuum chamber, hydrogen gas and argon gas are preferably introduced at a reduced pressure of from 10 Pa to 50 Pa.

As a second example, UV light cleaning may be used for the cleaning The UV light cleaning includes, for example, placing the substrate after the laser irradiation in a chamber that has a UV-light transmitting glass at the top thereof; and irradiating the substrate with UV light generated by a mercury lamp (or a xenon lamp). In the chamber, nitrogen gas or the like that contains ozone at a ratio of from 3% to 70% of ozone is preferably introduced, and cleaning may be performed by irradiating UV lights respectively having wavelengths of 185 nm and 254 nm that correspond to the ozone bond and the carbon bond respectively.

Another example is cleaning by directing a nozzle of a water jet such that the water jet is applied to the laser-irradiated portion and the portion is cleaned at an intensity of from 1 kgf/cm² to 50 kgf/cm². In this cleaning method, it is effective to use a suspension that includes powder, such as silica or alumina, which serves as fine abrasive grains. The whole surface may be cleaned by scanning the nozzle of the water jet, in which case the intensity thereof should be reduced to a value of from 2 kgf/cm² to 10 kgf/cm².

Further, the cleaning may be performed, after the laser irradiation, by further irradiating the substrate with an excimer laser or a UV laser at an energy of from 0.1 J/cm² to 1 J/cm², in which case the second laser irradiation may be performed only on the portion that was irradiated in the first laser irradiation or on the whole surface.

Process (f′)

As described above, in the process (g5), it is preferable that a portion other than the continuous circuit pattern that is formed by connecting separate and independent circuits to be finally obtained via current-carrying bridge portions is removed using a laser.

Therefore, in the process (f), the first metal film in the form of a continuous circuit pattern including the current-carrying bridge portions may be electroplated, in which case the process (g5) preferably includes a process (process (f)) of removing the current-carrying bridge portions from the first metal film forming the continuous circuit pattern in order to obtain a separate and independent circuit.

The process (process (f)) of removing the current-carrying bridge portions may be, for example, the following process.

Specifically, before the electroplating to be performed in the process (f), a resist is first applied to the current-carrying bridge portions that connect the separate and independent circuits to form a continuous circuit pattern. The resist may be coated according to an ink jet system whereby the resist may be applied to the portions that require the resist application, in a satisfactory manner. Alternatively, after the resist is applied to the whole surface, the resulting resist coating may be patterned using a laser or the like.

Next, the continuous circuit pattern is subjected to electroplating in the process (f) so as to allow a second metal film formed by the electroplating to grow on the first metal film formed by the electroless plating, whereby the thickness of the final metal film in the areas corresponding to the separate and independent circuits is increased.

Thereafter, the resist on the current-carrying bridge portions is removed with a resist remover liquid. Then, the current-carrying bridge portions of the first metal film formed by the electroless plating are removed by a treatment such as immersion of the substrate after the electroplating in an etching liquid or by a laser irradiation as in the (g5) process.

Through the above processes, separate and independent circuits are formed on the insulating base board.

In the process as described above, when the substrate after the electroplating is immersed in the etching liquid, in addition to the first metal film at the current-carrying bridge portions, the side surfaces of the metal films (first metal film formed by electroless plating and second metal film formed by electroplating) in the areas corresponding to the separate and independent circuits are simultaneously etched in the same amount. However, since the thickness of the first metal film at the current-carrying bridge portions is small, the thickness and width of the circuits are hardly affected.

Regarding the etching liquid to be used, the etching can be easily performed using a liquid having a slow etching speed such as an ammonium persulfate solution because the only material to be etched is the extremely-thin metal film at the current-carrying bridge portions.

In an embodiment, the resist is formed on a part of the continuous circuit pattern as well as on the current-carrying bridge portions, only the resist formed on the current-carrying bridge portions is removed, and etching is performed. When this process is performed, separate and independent circuits in which a thin film and a thick film are both included may be obtained. For the process, two kinds of resists having different solubilities from each other may be used. The use of two kinds of resists facilitates selective removal of the resist formed on the current-carrying bridge portions.

As described above, through the processes (a) to (g) of the present invention, a continuous circuit pattern made of a first metal film that has been formed in small thickness by electroless plating may be obtained without using a photoresist which has conventionally involved a complex process. In addition, as is performed in the process (f′), only the portions that serve as separate and independent circuit patterns may be subjected to electroplating so as to increase the thickness of the circuit but maintains the thickness of the first metal film at the current-carrying bridge portions that connect the separate and independent circuits small, whereby the first metal film at the current-carrying bridge portions can be easily removed by extremely mild etching. Furthermore, since electroplating provides a high deposition speed, it is quite easy to increase the thickness of the circuit, and the circuit can be fabricated efficiently.

### EXAMPLES

Hereinafter, the present invention will be further described in detail with reference to the following examples, but the examples should not be construed as limiting the present invention. Unless indicated otherwise, “%” and “part(s)” are based on mass.

### Example 1

### Formation of Adhesion Auxiliary Layer

As an insulating base board, a three-dimensional molded article was prepared by injection-molding of a liquid crystal polymer (VECTRA (trade name), manufactured by Polyplastics Co., Ltd.). The molded article was degreased, and the whole surface thereof was treated with a 10 N KOH aqueous solution, and then neutralized with a HCl aqueous solution.

Thereafter, the coating liquid for forming an adhesion auxiliary layer described below was spray-coated on the base board so as to form the adhesion auxiliary layer on the surface of the base board. Then, heat treatment was conducted at 180° C. for 30 minutes. The average thickness of the resultant adhesion auxiliary layer was 2 μm.

Here, the obtained multilayer material having the adhesion auxiliary layer was referred to as a substrate A.

Coating Liquid for Forming Adhesion Auxiliary Layer

20 parts by mass of a bisphenol A epoxy resin (EPIKOTE 828 (trade name) having an epoxy equivalent of 185, manufactured by Japan Epoxy Resins Co., Ltd.), 45 parts by mass of a cresol-novolak epoxy resin (EPICLON N-673 (trade name) having an epoxy equivalent of 215, manufactured by DIC Corporation), 30 parts by mass of a phenol-novolak resin (PHENOLITE (trade name) having a phenolic hydroxyl equivalent of 105, manufactured by DIC Corporation) were dissolved, while stirring and heating, in a mixture of 20 parts of ethyldiglycol acetate and 20 parts of solvent naphtha. The resultant solution was cooled to room temperature. Then, 30 parts by mass of a cyclohexanone varnish of a phenoxy resin composed of EPIKOTE 828 and a bisphenol S (YL6747H30 (trade name) having a nonvolatile content of 30% by mass and a weight average molecular weight of 47,000, manufactured by Japan Epoxy Resins Co., Ltd.), 0.8 parts by mass of 2-phenyl-4,5-bis(hydroxymethyl)imidazole, 2 parts by mass of finely pulverized silica, and 0.5 parts by mass of a silicone defoaming agent were added to the solution. To the resulting mixture, 10 parts by mass of a polymerization initiator polymer P synthesized according to the following process was further added so as to obtain an adhesion auxiliary liquid that included the polymerization initiator.

Synthesis of Polymerization Initiator Polymer P

Into a 300 mL three-necked flask, 30 g of propyleneglycol monomethylether (MFG) were added and heated at 75° C. A solution that included 8.1 g of [2-acryloyloxy]ethyl](4-benzoylbenzyl) dimethyl ammonium bromide, 9.9 g of 2-hydroxyethyl methacrylate, 13.5 g of isopropyl methacrylate, 0.43 g of dimethyl-2,2′-azobis(2-methylpropionate), and 30 g MFG was dropped into the flask over 2.5 hours. Thereafter, the reaction temperature was elevated to 80° C., the reaction was allowed to proceed for further 2 hours, as a result of which the polymer P that had a polymerization initiator group was obtained.

Preparation of Adhesion Layer

Next, in order to form an adhesion layer on the surface of the adhesion auxiliary layer, a coating liquid for forming an adhesion layer was spray-coated. The average thickness of the resulting adhesion layer was 1 μm. Subsequently, the adhesion layer was dried at 80° C. for 30 minutes, and then irradiated for 660 seconds at an irradiation power of 1.5 mW/cm² (wherein the irradiation power was measured with an integrating UV photometer UIT150 (trade name) and a light-receiving sensor UVD-5254 (trade name), both of which were manufactured by USHIO INC.) using a UV light exposure machine (Model UVF-5025, Lamp: UXM-501MD) manufactured by SAN-EI ELECTRIC CO., LTD. Thereafter, heat treatment at 140° C. was performed for 30 minute.

Here, the obtained multilayer material having the adhesion layer was referred to as a substrate B.

Coating Liquid for Forming Adhesion Layer

As described below, a polymer A (specific polymer) having a polymerizable group and an interaction group was synthesized first.

35 g of N,N-dimethylacetoamide were added into a 1000 mL three-necked flask, and heated to 75° C. under a nitrogen gas stream. Into the flask, a solution of 6.60 g of 2-hydroxyethyl acrylate, 28.4 g of 2-cyanoethyl acrylate, and 0.65 g of V-601 (trade name, manufactured by Wako Pure Chemical Industries, Ltd.) dissolved in 35 g of N,N-dimethyl acetoamide was dropped over 2.5 hours. After the dropping, the resulting reaction liquid was heated to 80° C. and further stirred for 3 hours. Thereafter, the reaction liquid was cooled to room temperature.

To the reaction solution, 0.29 g of di-tert-butyl hydroquinone, 0.29 g of di-butyl tin dilaurate, 18.56 g of KARENZ AOI (trade name, manufactured by SHOWA DENKO K. K.), and 19 g of N,N-dimethylacetoamide were added, and the resulting mixture was allowed to react at 55° C. for 4 hours. Then, 3.6 g of methanol were added to the resulting reaction liquid, and the reaction was allowed to proceed for further 1.5 hours. After the completion of the reaction, the reaction liquid was subjected to reprecipitation with a 1:1 mixture of ethyl acetate and hexane, and the resulting solid product was taken out, as a result of which 32 g of the polymer A having a polymerizable group and an interaction group were obtained.

The polymer A having a polymerizable group and an interaction group is considered to be a hydrophobic compound, because a film from of the polymer A alone exhibits a surface contact angle of 65 degrees in an environment of 25° C. and 50% RH after 54, of distilled water were dropped on the film and left to stand for 15 seconds.

Next, 10.5 parts by mass of the polymer A having a polymerizable group and an interaction group, 73.3 parts by mass of acetone, 33.9 parts by mass of methanol, and 4.8 parts by mass of N,N-dimethylacetoamide were mixed and stirred to prepare a coating liquid for forming an adhesion layer.

Application of Plating Catalyst

The substrate B having the adhesion layer was immersed for 30 minutes in a 1% solution of palladium nitrate in acetone, and then the substrate B was cleaned by immersed in acetone.

Subsequently, the substrate B was immersed for 15 minutes in a 1% solution of dimethylborane in a mixture of water and methanol (water/methanol=1/3), which served as a catalyst activating solution (reducing solution). Then, the substrate B was cleaned by immersion in acetone.

Here, the obtained multilayer material having the adhesion layer to which the plating catalyst was applied is referred to as a substrate C.

Electroless Plating

The substrate C that had the adhesion layer to which the plating catalyst was applied as described above was subjected to electroless plating at 60° C. for 5 minutes using an electroless plating bath having the following composition. The thickness of the resulting electroless plating copper film was 0.3 μm.

Here, the multilayer material having the electroless-plating copper film is referred to as a substrate D.

Composition of Electroless Plating Bath

| | | |
|---|---|---|
| Distilled water | 859 | g |
| Methanol | 850 | g |
| Copper sulfate | 18.1 | g |
| Ethylenediamine tetraacetic acid•2Na salt | 54.0 | g |
| Polyoxyethylene glycol (molecular weight: 1,000) | 0.18 | g |
| 2,2′-Bipyridyl | 1.8 | mg |
| 10% Ethylenediamine aqueous solution | 7.1 | g |
| 37% Formaldehyde aqueous solution | 9.8 | g |

The pH of the plating bath described above was adjusted to 12.5 (60° C.) with sodium hydroxide and sulfuric acid.

Laser Irradiation and Cleaning

Subsequently, laser irradiation was performed as follows.

The laser used was a YAG laser. The pattern width of the laser irradiation was controlled by adjusting the beam diameter on the surface of the electroless-plating copper film (adhesion layer) by adjusting the degree of defocus by regulating the focal length of the lens or the distance from the electroless plating copper film (adhesion layer). With this arrangement, the laser beam was irradiated on the other area on the electroless plating copper film of substrate D than a continuous circuit pattern that was formed by connecting separate and independent circuits to be finally obtained via current-carrying bridge portions. The laser irradiation energy was adjusted to 100 μJ/pulse. Laser irradiation was repeated until the metal in the other area than the continuous circuit pattern was completely removed ((g4) process).

Thereafter, the substrate D after the laser irradiation was immersed in an ethanol solution for 5 minutes, and then cleaned by spraying a water/ethanol mixed solution by a shower and subsequently rinsing the substrate with running distilled water.

In this way, a substrate of which only the portion corresponding to the continuous circuit pattern formed by connecting separate and independent circuits to be finally obtained via current-carrying bridge portions was coated with a copper thin film (electroless-plating copper film) deposited by the electroless plating was obtained.

The substrate was degreased with a 50 g/L solution of ACECLEAN A-220 (trade name) manufactured by OKUNO Pharmaceuticals Co., Ltd. under the condition of 50° C. for 2 seconds.

The thus obtained substrate having a copper thin film pattern was referred to as a substrate E.

Formation of Plating Resist Pattern for Electroplating

First, the surface of the copper thin film pattern of the substrate E was cleaned with a soft etching liquid based on a mixture of hydrogen peroxide and sulfuric acid. Thereafter, a dry film resist (ALPHO NIT3025 (trade name), manufactured by Nichigo-Morton Co., Ltd.) was laminated onto the copper thin film pattern of the substrate E at a temperature of 110±10° C. and a pressure of 0.35±0.05 MPa.

Pattern exposure was conducted at 130 mJ/cm² by irradiating UV light of an ultra-high pressure mercury lamp, using guide holes as positional references, such that the resist after development would cover only current-carrying bridge portions of the copper thin film pattern, which portions would become eventually unnecessary. Then, the dry film resist was developed with a 1.5% sodium carbonate aqueous solution at a temperature of 30° C. and a spray pressure of 0.15 MPa, thereby forming a plating resist pattern for electroplating.

Electroplating

Thereafter, electroplating was performed using the copper thin film pattern (electroless plating copper film) as a feeder layer and using a copper electroplating bath having the following composition. For the electroplating, the area (the area of the copper thin film pattern) covered with the electroless plating copper film was calculated based on the pattern shape. On the basis of the calculated area, electroplating was performed for 20 minutes at a current power unit area of 3 A/dm² and a liquid temperature of 25° C. The thickness of the resulting electroplating copper film was 18 μm.

Composition of Electroplating Bath

| | | |
|---|---|---|
| Copper sulfate | 38 | g |
| Sulfuric acid | 95 | g |
| Hydrochloric acid | 1 | mL |
| COPPER GLEAM PCM (trade name, manufactured by | 3 | mL |
| Meltex Inc.) | | |
| Water | 500 | g |

Further, nickel was electroplated on the resultant electroplating copper film as follows.

A mixed liquid of a 18 mL/L solution of ACNA B-40 (trade name) manufactured by OKUNO CHEMICAL INDUSTRIES CO., LTD, a 1 mL/L solution of ACNA B-10 (trade name) manufactured by OKUNO CHEMICAL INDUSTRIES CO., LTD., a 270 g/L solution of nickel sulfate, and a 50 g/L solution of nickel chloride was used as a plating bath, and the area covered with the electroplating copper film was calculated based on the pattern shape. On the basis of the calculated area, electroplating was performed for 25 minutes at a current per unit area of 3 A/dm² and a liquid temperature of 50° C.

Subsequently, gold was electroplated on the resultant electroplating nickel film as follows.

TEMPELEX 401 (trade name) was used as a plating bath, and the area covered with the electroplating nickel film was calculated based on the pattern shape. On the basis of the calculated area, electroplating was performed for 90 seconds at a current per unit area of 1 A/dm² and a liquid temperature of 65° C.

Removal of Plating Resist Pattern and Etching

The plating resist pattern was detached and removed using a resist remover liquid, which is a 5% sodium hydroxide aqueous solution, at 60° C. and a spray pressure of 0.2 MPa.

Then, etching was performed using a YAG laser. The pattern width of the laser irradiation was controlled by adjusting the beam diameter on the surface of the electroplating film by adjustment of the degree of defocus by regulating the focal length of the lens or the distance from the electroplating film. The laser beam was irradiated only on the current-carrying bridge portions, which connected the separate and independent circuits to be finally obtained. The laser irradiation energy was set to 100 μJ/pulse. The laser irradiation was repeated until the metal at the current-carrying bridge portions was completely removed ((g5) process). In this way, a circuit board having desired separate and independent circuits was obtained.

Thereafter, the circuit board was immersed in an ethanol solution for 5 minutes, and then cleaned by showering a water/ethanol mixed solution and subsequently rinsing with running distilled water.

In this way, a circuit board of Example 1 was obtained.

### Example 2

The substrate B having an adhesion layer was obtained in the same manner as in Example 1.

Thereafter, the substrate B was subjected to the following processes.

Laser Irradiation and Cleaning

Subsequently, laser irradiation was performed as follows.

The laser used was a carbon dioxide gas laser. The pattern width of the laser irradiation was controlled by adjusting the beam diameter of the laser on the surface of the adhesion layer by adjustment of the degree of defocus by regulating the focal length of the lens or the distance from the adhesion layer. Under such a control, the laser beam was irradiated on the other area on the adhesion layer of the substrate B than the continuous circuit pattern formed by connecting the separate and independent circuits to be finally obtained via the current-carrying bridge portions. The laser irradiation energy was set to 0.2 J/cm² ((g2) process).

Then, the substrate B after the laser irradiation was immersed in an acetone solution for 5 minutes, and cleaned by showering a water/acetone mixed solution and subsequently rinsing with running distilled water.

Application of Plating Catalyst and Electroless Plating

The substrate after the laser irradiation was subjected to the processes of application of plating catalyst and electroless plating, in the same manner as in Example 1.

Formation of Plating Resist Pattern for Electroplating, Electroplating, and Removal of Plating Resist Pattern and Etching

Then, the substrate having the copper thin film pattern (electroless plating copper film) obtained by the electroless plating was subjected to the processes of formation of plating resist pattern for electroplating, electroplating, and removal of plating resist pattern and etching ((g5) process) in the same manner as in Example 1, whereby a circuit board of Example 2 was obtained.

### Example 3

The substrate C having an adhesion layer to which a plating catalyst was applied was obtained in the same manner as in Example 1.

Thereafter, the substrate C was subjected to the following processes.

Laser Irradiation and Cleaning

Subsequently, laser irradiation was preformed as follows.

The laser used was a carbon dioxide gas laser. The pattern width of the laser irradiation was controlled by adjusting the beam diameter of the laser on the surface of the adhesion layer by adjustment of the degree of defocus by regulating the focal length of the lens or the distance from the adhesion layer. Under such a control, the laser beam was irradiated on the other area on the adhesion layer of the substrate C than the continuous circuit pattern formed by connecting the separate and independent circuits to be finally obtained via the current-carrying bridge portions. The laser irradiation energy was set to 15 J/cm² ((g3) process).

Then, the substrate C after the laser irradiation was immersed in an acetone solution for 5 minutes, and cleaned by showering a water/acetone mixed solution and subsequently rinsing with running distilled water.

Electroless Plating

The substrate after the laser irradiation was subjected to the process of electroless Plating in the same manner as in Example 1.

Formation of Plating Resist Pattern for Electroplating, Electroplating, and Removal of Plating Resist Pattern and Etching

Then, the substrate having the copper thin film pattern (electroless plating copper film) obtained by the electroless plating was subjected to the processes of formation of plating resist pattern for electroplating, electroplating, and removal of plating resist pattern and etching ((g5) process) in the same manner as in Example 1, whereby a circuit board of Example 3 was obtained.

### Example 4

The substrate A having an adhesion auxiliary layer was obtained in the same manner as in Example 1.

Thereafter, the substrate A was subjected to the following processes.

Laser Irradiation and Cleaning

Subsequently, laser irradiation was performed as follows.

The laser used was a carbon dioxide gas laser. The pattern width of the laser irradiation was controlled by adjusting the beam diameter on the surface of the adhesion auxiliary layer by adjustment of the degree of defocus by regulating the focal length of the lens or the distance from the adhesion auxiliary layer. Under such a control, the laser beam was irradiated on the other area on the adhesion auxiliary layer of the substrate A than the continuous circuit pattern formed by connecting the separate and independent circuits to be finally obtained via the current-carrying bridge portions. The laser irradiation energy was adjusted to 0.8 J/cm² ((g1) process).

Then, the substrate A after the laser irradiation was immersed in an acetone solution for 5 minutes, and cleaned by showering a water/acetone mixed solution and subsequently rinsing with running distilled water.

Formation of Adhesion Layer

Next, on the surface of the adhesion auxiliary layer after the laser irradiation, the coating liquid for forming an adhesion layer used in Example 1 was spray-coated. The average thickness of the resulting adhesion layer was 1 μm. Then, after drying at 80° C. for 30 seconds, the adhesion layer was irradiated for 660 seconds at an irradiation power of 1.5 mW/cm² (wherein the irradiation power was measured with an integrating UV photometer UIT150 (trade name) and a light-receiving sensor UVD-5254 (trade name), both which were manufactured by USHIO INC.), using a UV light exposure machine (model UVF-502S, lamp: UXM-501MD) manufactured by SAN-EI ELECTRIC CO., LTD.

Then, the substrate was immersed in acetone for 5 minutes while the acetone was stirred, and then the substrate was cleaned with distilled water. Thereafter, the substrate was heated at 140° C. for 30 minutes.

As a result, a substrate having a patterned adhesion layer was obtained.

Application of Plating Catalyst and Electroless Plating

The substrate having the patterned adhesion layer was subjected to the processes of application of plating catalyst and electroless plating, in the same manner as in Example 1.

Formation of Plating Resist Pattern for Electroplating, Electroplating, and Removal of Plating Resist Pattern and Etching

Then, the substrate having the copper thin film pattern (electroless plating copper film) obtained by the electroless plating was subjected to the processes of formation of plating resist pattern for electroplating, electroplating, and removal of plating resist pattern and etching ((g5) process) in the same manner as in Example 1, whereby a circuit board of Example 4 was obtained.

### Example 5

The processes of formation of adhesion auxiliary layer, formation of adhesion layer, application of plating catalyst, electroless plating, laser irradiation ((g4 process), and cleaning, formation of plating resist pattern for electroplating, and electroplating were performed in the same manner as in Example 1, and then the following process of removal of plating resist pattern and etching was performed whereby a circuit board of Example 5 was obtained.

Removal of Plating Resist Pattern and Etching

The plating resist pattern was removed using a resist remover liquid, which is a 5% sodium hydroxide aqueous solution, at 60° C. and a spray pressure of 0.2 MPa.

Thereafter, the current-carrying bridge portions that connected the separate and independent circuits to be finally obtained were removed using a soft etching liquid based on a mixture of hydrogen peroxide and sulfuric acid. Through the above processes, a circuit board having desired separate and independent circuits was obtained.

In this way, a circuit board of Example 5 was obtained.

### Example 6

The substrate A having an adhesion auxiliary layer was obtained in the same manner as in Example 1.

Thereafter, the substrate A was subjected to the following processes.

Formation of Adhesion Layer

Next, on the surface of the adhesion auxiliary layer, the coating liquid for forming an adhesion layer used in Example 1 was spray-coated. The average thickness of the resulting coating layer was 1 μm. Subsequently, a portion of the coating layer that corresponded to the continuous circuit pattern formed by connecting separate and independent circuits to be finally obtained via current-carrying bridge portions was irradiated with a UV YAG laser (YAG forth harmonic wave) having a wavelength of 266 nm while the scanning time was controlled such that the irradiation energy at an irradiation spot was 1,000 mJ. During the laser irradiation, the laser beam was focused with a lens, and the laser beam and the substrate A were moved relative to each other such that a portion that required irradiation was irradiated with the laser beam. The pattern width of the laser irradiation was controlled by adjusting the beam diameter on the surface of the coating layer of the substrate A by adjustment of the degree of defocus by regulating the focal length of the lens or the position of the substrate A. Fine portions of the pattern, which could not be drawn by a thick beam, were drawn by forming a thin beam by setting the position of the coating layer of the substrate A to match the focus position.

Then, the substrate was immersed in acetone for 5 minutes while the acetone was stirred, and the substrate was subsequently cleaned with distilled water. Thereafter, the substrate was heated at 140° C. for 30 minutes.

Through the above processes, a substrate having a patterned adhesion layer was obtained.

Application of Plating Catalyst and Electroless Plating

The substrate having the patterned adhesion layer was subjected to the processes of application of plating catalyst and electroless plating, in the same manner as in Example 1.

Formation of Plating Resist Pattern for Electroplating, Electroplating, and Removal of Plating Resist Pattern and Etching

Then, the substrate having the copper thin film pattern (electroless plating copper film) obtained by the electroless plating was subjected to the processes of formation of plating resist pattern for electroplating, electroplating, and removal of plating resist pattern and etching ((g5) process) in the same manner as in Example 1, whereby a circuit board of Example 6 was obtained.

### Example 7

The substrate A having an adhesion auxiliary layer was obtained in the same manner as in Example 1.

Thereafter, the substrate A was subjected to the following processes.

Formation of Adhesion Layer

Next, on the surface of the adhesion auxiliary layer, the coating liquid for forming an adhesion layer used in Example 1 was spray-coated. The average thickness of the resulting adhesion (coating) layer was 1 μm. Subsequently, a portion of the coating layer that corresponded to the continuous circuit pattern formed by connecting separate and independent circuits to be finally obtained via current-carrying bridge portions was irradiated with a UV YAG laser (YAG forth harmonic wave) having a wavelength of 266 nm while the scanning time was controlled such that the irradiation energy at an irradiation spot was 1,000 mJ. During the laser irradiation, the laser beam was focused with a lens, and the laser beam and the substrate A were moved relative to each other such that a portion that required irradiation was irradiated with the laser beam. The pattern width of the laser irradiation was controlled by adjusting the beam diameter on the surface of the coating layer of the substrate A by adjustment of the degree of defocus by regulating the focal length of the lens or the position of the substrate A. Fine portions of the pattern, which could not be drawn by a thick beam, were drawn by forming a thin beam by setting the position of the coating layer of the substrate A to match the focus position.

Then, the substrate was immersed in acetone for 5 minutes while the acetone was stirred, and the substrate was subsequently cleaned with distilled water. Thereafter, the substrate was heated at 140° C. for 30 minutes.

Through the above process, a substrate having a patterned adhesion layer was obtained.

Laser Irradiation and Cleaning

Subsequently, laser irradiation was performed as follows.

The laser used was a carbon dioxide gas laser. The pattern width of the laser irradiation was controlled by adjusting the beam diameter of the laser on the surface of the adhesion auxiliary layer by adjustment of the degree of defocus by regulating the focal length of the lens or the distance from the adhesion auxiliary layer. Under such a control, the laser beam was irradiated on the other area (the area on which the adhesion layer was not formed) on the adhesion auxiliary layer than the continuous circuit pattern formed by connecting the separate and independent circuits to be finally obtained via the current-carrying bridge portions. The laser irradiation energy was adjusted to 0.8 J/cm² ((g1) process).

Then, the substrate after the laser irradiation was immersed in an acetone solution for 5 minutes, and cleaned by showering a water/acetone mixed solution and subsequently rinsing with running distilled water.

Application of Plating Catalyst and Electroless Plating

The substrate having the patterned adhesion layer was subjected to the processes of application of plating catalyst and electroless plating in the same manner as in Example 1.

Formation of Plating Resist Pattern for Electroplating, Electroplating, and Removal of Plating Resist Pattern and Etching

Then, the substrate having the copper thin film pattern (electroless-plating copper film) obtained by the electroless plating was subjected to the processes of formation of plating resist pattern for electroplating, electroplating, and removal of plating resist pattern and etching ((g5) process) in the same manner as in Example 1, whereby a circuit board of Example 7 was obtained.

### Comparative Example 1

As an insulating base board, a three-dimensional molded article was prepared by injection-molding of a liquid crystal polymer (VECTRA (trade name), manufactured by Polyplastics Co., Ltd.). The molded article was degreased, and the whole surface thereof was treated with a 12.5 N NaOH solution at 80° C. for 60 minutes, thereby forming fine unevenness. Then, after the etched resin was thoroughly removed by washing the insulating base board with water at 60° C. for 5 minutes, neutralization with an HCl aqueous solution was performed.

The insulating base board treated above was subjected to the processes of application of plating catalyst and electroless plating in the same manner as in Example 1. Subsequently, a metal pattern was formed on the insulating base board by using a YAG laser by irradiating a laser beam on the other area than a continuous circuit pattern formed by connecting separate and independent circuits to be obtained finally via current-carrying bridge portions, in the same manner as in Example 1. Then, a resist pattern was formed to cover only the current-carrying bridge portions of the metal pattern. Further, electroplating with copper, nickel, and gold was performed in the same manner as in Example 1, and then the resist was removed. Thereafter, in the same manner as in Example 5, the electroless plating copper film at the current-carrying bridge portions was removed using a soft etching liquid based on a mixture of hydrogen peroxide and sulfuric acid, as a result of which the copper of the electroless plating copper film at the current-carrying bridge portions is removed. In this way, a circuit board of Comparative Example 1 was obtained.

Evaluation

Formability of Fine Circuits

Formability of fine circuits was evaluated as follows. When fabricating circuit board samples in Examples and Comparative Examples, the diameter of the laser beam was adjusted aiming at forming circuit having a comb-shaped wiring pattern with L/S=10 μm/10 μm.

Ten samples were fabricated for each Example or Comparative Example, in the manner as described above. These ten samples were checked with respect to short-circuit failures and disconnection failures. A sample was ranked A if the sample had no short-circuit failure or disconnection failure, ranked B if the sample had from one to two failures, ranked C if the sample had three or more failures, and ranked D if the wiring was not formed. The results are shown in Table 2.

Observation of Wiring Shape

Fine wires that was formed in the comb-shaped wiring pattern in the same manner as in the evaluation of the formability of fine circuits described above were observed with a color 3D laser microscope VK-9700 (trade name, manufactured by KEYENCE Corp.). Comparison was made on the observed shape of the wires. The results are shown in Table 2.

Observation of Residues Between Circuits

The spaces between the fine wires that were formed in the comb-shaped circuit pattern in the same manner as in the evaluation of the formability of fine circuits described above were observed with a color 3D laser microscope VK-9700 (trade name, manufactured by KEYENCE Corp.) to check whether or not plating metal residues or plating catalyst residues remained therein. A sample was ranked A if it had no residues, ranked B if it had only a slight residues, ranked C if it had several residues, and ranked D if it had a lot of residues. The results are shown in Table 2.

Evaluation of Adhesion

Adhesion was evaluated as follows. A solid pattern of metal in a size of 2 cm-square was formed when the circuit board was fabricated in each of Examples and Comparative Example. The adhesion of the resulting plating layer was evaluated by a grid cell detachment test of 100 cells in accordance with JIS H8504 and C5012 (which is incorporated herein by reference). When 100 grid cells are observed, a sample is ranked A if it had no detached grid cell, ranked B if it had from one to two detached grid cells, ranked C if it had from three to five detached grid cells, and ranked D if it had more than five detached grid cells. The results are shown in Table 2.

TABLE 2

| | | | Resides | Need for | |
|---|---|---|---|---|---|
| | Formability of 10 μm | | between | developing | |
| | fine circuit | Wire shape | wires | adhesion layer | Adhesion |
| Example 1 | B | Uneven | C | Unnecessary | A |
| Example 2 | A | Uneven | A | Unnecessary | A |
| Example 3 | B | Uneven | B | Unnecessary | A |
| Example 4 | B | Uneven | A | Necessary | A |
| Example 5 | B | Uneven | C | Unnecessary | B |
| Example 6 | A | Straight line | B | Necessary | A |
| Example 7 | A | Straight line | A | Necessary | A |
| Comparative | C | Uneven | C | Unnecessary | C |
| Example 1 | | | | | |

As shown in Table 2, the method of fabricating a circuit board according to the present invention provides a circuit board which has a circuit exhibiting excellent adhesion to the base board and in which the amount of residues remaining on a non-circuit portion is reduced. In addition, according to the method of fabricating a circuit board according to the present invention, a 10-μm fine wiring that has no, or only a few, short-circuit failures and/or disconnection failures can be fabricated.

From the viewpoint of formability of fine wiring, residues remaining between wires, and adhesion, an embodiment exemplified by Example 2, in which the process (g2) is employed and development of the adhesion layer is unnecessary, is preferred.

Further, as is clear from the results shown in Table 2, depending on the manner of the process (b) and/or the manner of the process (g), development of the adhesion layer is unnecessary. Selection of an embodiment in which the development of the adhesion layer is unnecessary allows the production processes to be simplified.

All publications, patent applications, and technical standards mentioned in this specification are herein incorporated by reference to the same extent as if each individual publication, patent application, or technical standard was specifically and individually indicated to be incorporated by reference.

What is claimed is:

1. A method of fabricating a circuit board, comprising, in the following order:
(a) forming an adhesion auxiliary layer on a surface of an insulating base board;
(b) forming an adhesion layer on a surface of the adhesion auxiliary layer, the adhesion layer comprising a polymer compound having a polymerizable group and a functional group capable of interacting with a plating catalyst or a precursor thereof;
(c) fixing the adhesion layer to the adhesion auxiliary layer by applying energy to the adhesion layer;
(d) applying a plating catalyst or a precursor thereof to the adhesion layer that is fixed to the adhesion auxiliary layer;
(e) forming a first metal film by electroless plating on the adhesion layer having had the plating catalyst or a precursor thereof applied thereto; and
(f) performing electroplating by using the first metal film formed by electroless plating;
wherein the method further includes (g) partly removing, by irradiating a laser beam, an area corresponding to a non-circuit portion in any of: the adhesion auxiliary layer prior to (b) the forming of the adhesion layer, the adhesion layer that is fixed to the adhesion auxiliary layer prior to (d) the applying of a plating catalyst or a precursor thereof, the adhesion layer having had the plating catalyst or a precursor thereof applied thereto prior to (e) the forming of the first metal film, or the first metal film prior to (f) the performing of the electroplating.

2. The method of fabricating a circuit board according to claim 1, wherein any one of dip coating, spray coating or ink jet coating is used for the forming of the adhesion auxiliary layer.

3. The method of fabricating a circuit board according to claim 1, wherein any one of dip coating, spray coating or ink jet coating is used for the forming of the adhesion layer.

4. The method of fabricating a circuit board according to claim 1, wherein the irradiation energy of the laser beam is from 0.1 J/cm² to 1.0 J/cm².

5. The method of fabricating a circuit board according to claim 1, wherein the thickness of the first metal film formed by electroless plating is from 0.2 μm to 2.0 μm.

6. The method of fabricating a circuit board according to claim 1, wherein the thickness of the first metal film formed by electroless plating is from 0.3 μm to 1.5 μm.

7. The method of fabricating a circuit board according to claim 1, wherein the thickness of the first metal film formed by electroless plating is from 0.5 μm to 1.0 μm.

8. The method of fabricating a circuit board according to claim 1, wherein the polymer compound having a polymerizable group and a functional group capable of interacting with a plating catalyst or a precursor thereof has the polymerizable group at a terminal of the main chain thereof or at a side chain thereof.

9. The method of fabricating a circuit board according to claim 1, wherein the polymer compound having a polymerizable group and a functional group capable of interacting with a plating catalyst or a precursor thereof has the polymerizable group at a side chain thereof.

10. The method of fabricating a circuit board according to claim 1, wherein the polymer compound having a polymerizable group and a functional group capable of interacting with a plating catalyst or a precursor thereof is a hydrophobic compound.

11. The method of fabricating a circuit board according to claim 1, wherein the polymer compound having a polymerizable group and a functional group capable of interacting with a plating catalyst or a precursor thereof is a compound having a cyano group serving as the functional group capable of interacting with the plating catalyst or precursor thereof.

12. The method of fabricating a circuit board according to claim 1, wherein the polymer compound having a polymerizable group and a functional group capable of interacting with a plating catalyst or a precursor thereof is a compound having an alkylcyano group serving as the functional group capable of interacting with the plating catalyst or precursor thereof.

13. The method of fabricating a circuit board according to claim 1, wherein the polymer compound having a polymerizable group and a functional group capable of interacting with a plating catalyst or a precursor thereof is a compound having a vinyl group serving as the polymerizable group.

14. The method of fabricating a circuit board according to claim 1, wherein the polymer compound having a polymerizable group and a functional group capable of interacting with a plating catalyst or a precursor thereof is a compound having an allyl group serving as the polymerizable group.

15. The method of fabricating a circuit board according to claim 1, wherein the polymer compound having a polymerizable group and a functional group capable of interacting with a plating catalyst or a precursor thereof is a compound having a (meth)acryl group serving as the polymerizable group.

16. The method of fabricating a circuit board according to claim 1, wherein the polymer compound having a polymerizable group and a functional group capable of interacting with a plating catalyst or a precursor thereof is a compound having a vinyl group serving as the polymerizable group, and the weight average molecular weight of the polymer compound is from 1,000 to 700,000.

17. The method of fabricating a circuit board according to claim 1, wherein the polymer compound having a polymerizable group and a functional group capable of interacting with a plating catalyst or a precursor thereof is a compound having a vinyl group serving as the polymerizable group, and the polymerization degree of the polymer compound is from 10 to 7,000.

18. A method of fabricating a circuit board, comprising, in the following order:
(a) forming an adhesion auxiliary layer on a surface of an insulating base board;
(b) forming an adhesion layer on a surface of the adhesion auxiliary layer, the adhesion layer comprising a plating catalyst or a precursor thereof and a polymer compound having a polymerizable group and a functional group capable of interacting with the plating catalyst or precursor thereof;
(c) fixing the adhesion layer to the adhesion auxiliary layer by applying energy to the adhesion layer;
(e) forming a first metal film by electroless plating on the adhesion layer that is fixed to the adhesion auxiliary layer; and
(f) performing electroplating by using the first metal film formed by electroless plating;
wherein the method further includes (g) partly removing, by irradiating a laser beam, an area corresponding to a non-circuit portion in any of: the adhesion auxiliary layer prior to (b) the forming of the adhesion layer, the adhesion layer prior to (c) the fixing the adhesion layer prior to (e) the forming of the first metal film, or the first metal film prior to (f) the performing of the electroplating.
